(19) United States
(12) Patent Application Publication
(10) Pub. No.: US 2022/0082719 A1
(43) Pub. Date: Mar. 17, 2022

(54) RESERVOIR PERFORMANCE SYSTEM

(71) Applicant: Schlumberger Technology Corporation, Sugar Land, TX (US)

(72) Inventors: Shripad Suhas Biniwale, Abingdon (GB); Vijaya Halabe, Houston, TX (US); Jonathan Nitura, Kuala Lumpur (MY); Nur Erziyati Rabtah Seruji, Kuala Lumpur (MY); Nelson Jose Gonzalez Rodriguez, Houston, TX (US); Rena Alia Ramdzani, Kuala Lumpur (MY); Oluwole Adesola Talabi, Kuala Lumpur (MY); Omkar Koundarkar, Pune (IN); Muzahidin Muhamed Salim, Abu Dhabi (AE); Rajesh Trivedi, Kuala Lumpur (MY); Azhar Ahmad, Shah Alam (MY)

(21) Appl. No.: 17/310,084

(22) PCT Filed: Jan. 17, 2020
(86) PCT No.: PCT/US2020/013976

§ 371 Date: Jul. 15, 2021

Related U.S. Application Data
(60) Provisional application No. 62/793,877, filed on Jan. 17, 2019.

(51) Int. Cl. G01V 1/28; G01V 1/30; G06F 30/28

(52) U.S. Cl. CPC G01V 1/282; G01V 2210/66; G06F 30/28; G01V 1/306

(57) ABSTRACT

A system can include a back-end framework that validates a reservoir model and a production network model using field data to generate a validated integrated model based at least in part on the validated reservoir model and the validated production network model; and a front-end web portal application that receives integrated model simulation data from execution of a simulation using the validated integrated model.

### RELATED APPLICATION

This application claims priority to and the benefit of a U.S. Provisional application having Ser. No. 62/793,877, filed 17 Jan. 2019, which is incorporated by reference herein.

### BACKGROUND

A reservoir can be a subsurface formation that can be characterized at least in part by its porosity and fluid permeability. As an example, a reservoir may be part of a basin such as a sedimentary basin. A basin can be a depression (e.g., caused by plate tectonic activity, subsidence, etc.) in which sediments accumulate. As an example, where hydrocarbon source rocks occur in combination with appropriate depth and duration of burial, a petroleum system may develop within a basin, which may form a reservoir that includes hydrocarbon fluids (e.g., oil, gas, etc.).

### SUMMARY

A system can include a back-end framework that validates a reservoir model and a production network model using field data to generate a validated integrated model based at least in part on the validated reservoir model and the validated production network model; and a front-end web portal application that receives integrated model simulation data from execution of a simulation using the validated integrated model. A method can include, via a back-end framework, validating a reservoir model and a production network model using field data to generate a validated integrated model based at least in part on the validated reservoir model and the validated production network model; executing a simulation using the validated integrated model to generate integrated model simulation data; and transmitting at least a portion of the integrated model simulation data to a front-end web portal application. One or more computer-readable storage media can include processor-executable instructions to instruct a computing system to: via a back-end framework, validate a reservoir model and a production network model using field data to generate a validated integrated model based at least in part on the validated reservoir model and the validated production network model; execute a simulation using the validated integrated model to generate integrated model simulation data; and transmit at least a portion of the integrated model simulation data to a front-end web portal application. Various other apparatuses, systems, methods, etc., are also disclosed.

This summary is provided to introduce a selection of concepts that are further described below in the detailed description. This summary is not intended to identify key or essential features of the claimed subject matter, nor is it intended to be used as an aid in limiting the scope of the claimed subject matter.

### BRIEF DESCRIPTION OF THE DRAWINGS

Features and advantages of the described implementations can be more readily understood by reference to the following description taken in conjunction with the accompanying drawings.

FIG. 1 illustrates an example system that includes various components for simulating a geological environment;

FIG. 2 illustrates examples of a basin, a convention and a system;

FIG. 3 illustrates an example of a system;

FIG. 4 illustrates examples of systems;

FIG. 5 illustrates an example of a network;

FIG. 6 illustrates an example of a system and an example of a method;

FIG. 7 illustrates an example of a system;

FIG. 8 illustrates an example of a method;

FIG. 9 illustrates an example of a GUI;

FIG. 10 illustrates an example of a method;

FIG. 11 illustrates an example of a workflow;

FIG. 12 illustrates examples of workflows;

FIG. 13 illustrates examples of systems;

FIG. 14 illustrates examples of model components and workflows;

FIG. 15 illustrates an example of an architecture;

FIG. 16 illustrates an example of a process GUI and an example of a system;

FIG. 17 illustrates an example of a GUI;

FIG. 18 illustrates examples of GUIs;

FIG. 19 illustrates examples of workflows associated with components of a system;

FIG. 20 illustrates an example of an architecture;

FIG. 21 illustrates examples of GUIs;

FIG. 22 illustrates examples of GUIs of a system;

FIG. 23 illustrates an example of a system, an example of a method and an example of a computing system;

FIG. 24 illustrates examples of computer and network equipment; and

FIG. 25 illustrates example components of a system and a networked system.

### DETAILED DESCRIPTION

This description is not to be taken in a limiting sense, but rather is made merely for the purpose of describing the general principles of the implementations. The scope of the described implementations should be ascertained with reference to the issued claims.

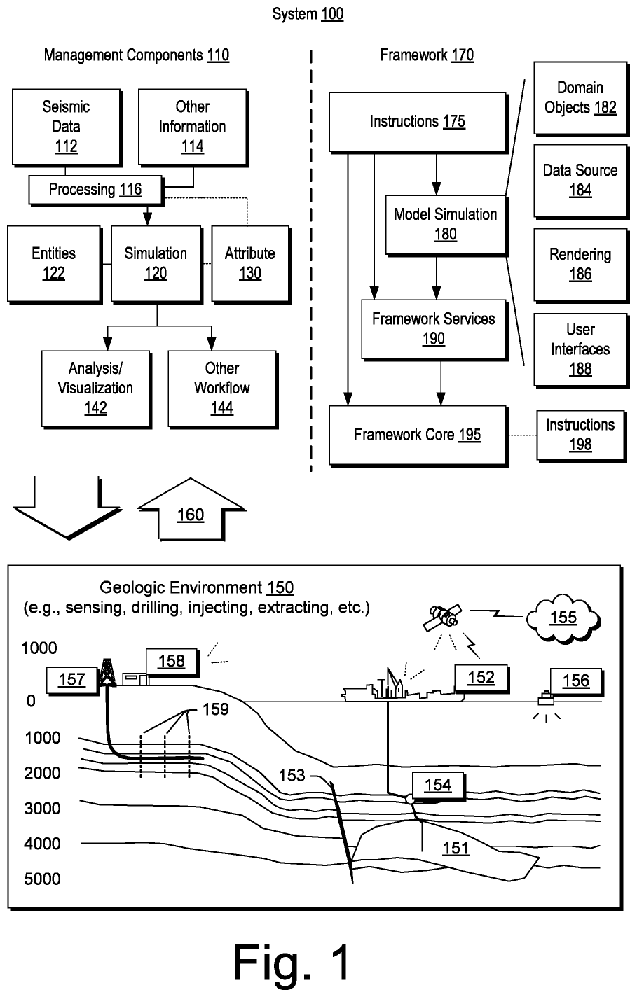

FIG. 1 shows an example of a system 100 that includes various management components 110 to manage various aspects of a geologic environment 150 (e.g., an environment that includes a sedimentary basin, a reservoir 151, one or more faults 153, one or more fractures 159, etc.). For example, the management components 110 may allow for direct or indirect management of sensing, drilling, injecting, extracting, etc., with respect to the geologic environment 150. In turn, further information about the geologic environment 150 may become available as feedback 160 (e.g., optionally as input to one or more of the management components 110).

In the example of FIG. 1, the management components 110 include a seismic data component 112, an additional information component 114 (e.g., well/logging data, etc.), a processing component 116, a simulation component 120, an attribute component 130, an analysis/visualization component 142 and a workflow component 144. In operation, as an example, seismic data and other information provided per the components 112 and 114 may be input to the simulation component 120.

In the example of FIG. 1, the seismic data component 112 may provide seismic data as acquired via reflection seismology, which finds use in geophysics, for example, to estimate properties of subsurface formations. As an example, reflection seismology may provide seismic data representing waves of elastic energy (e.g., as transmitted by P-waves and S-waves, in a frequency range of approximately 1 Hz to approximately 100 Hz). Seismic data may be processed and interpreted, for example, to understand better composition, fluid content, extent and geometry of subsurface rocks. Such interpretation results can be utilized to plan, perform, etc., one or more operations for production of fluid from a reservoir (e.g., reservoir rock, etc.).

Field acquisition equipment may be utilized to acquire seismic data, which may be in the form of traces where a trace can include values organized with respect to time and/or depth (e.g., consider 1D, 2D, 3D or 4D seismic data). For example, consider acquisition equipment that acquires digital samples at a rate of one sample per approximately 4 ms. Given a speed of sound in a medium or media, a sample rate may be converted to an approximate distance. For example, the speed of sound in rock may be on the order of around 5 km per second. Thus, a sample time spacing of approximately 4 ms would correspond to a sample “depth” spacing of about 10 meters (e.g., assuming a path length from source to boundary and boundary to sensor). As an example, a trace may be about 4 seconds in duration; thus, for a sampling rate of one sample at about 4 ms intervals, such a trace would include about 1000 samples where latter acquired samples correspond to deeper reflection boundaries. If the 4 second trace duration of the foregoing example is divided by two (e.g., to account for reflection), for a vertically aligned source and sensor, a deepest boundary depth may be estimated to be about 10 km (e.g., assuming a speed of sound of about 5 km per second).

As an example, the simulation component 120 may include features that allow for building a model or models of a geologic environment. As an example, a model may be a simulated version of a geologic environment. As an example, a simulator may include features for simulating physical phenomena in a geologic environment based at least in part on a model or models. As an example, one or more of the management components 110 may be part of a seismic-to-simulation framework and may include or may be operatively coupled to, for example, one or more components that can simulate physical phenomena in a geologic environment. For example, a simulator, such as a reservoir simulator, can simulate fluid flow in a geologic environment based at least in part on a model that can be generated via a framework that receives seismic data. A simulator can be a computerized system (e.g., a computing system) that can execute instructions using one or more processors to solve a system of equations that describe physical phenomena subject to various constraints. The system of equations may be spatial defined (e.g., numerically discretized) according to a spatial model that that includes layers of rock, geobodies, etc., that have corresponding positions that can be based on interpretation of seismic and/or other data. A spatial model may be a cell-based model where cells are defined by a grid (e.g., a mesh). A cell in a cell-based model can represent a physical area or volume in a geologic environment where the cell can be assigned physical properties (e.g., permeability, fluid properties, etc.) that may be germane to one or more physical phenomena (e.g., fluid volume, fluid flow, pressure, etc.). A reservoir simulation model can be a spatial model that may be cell-based.

A simulator can be utilized to simulate the exploitation of a real reservoir, for example, to examine different productions scenarios to find an optimal one before production or further production occurs. A reservoir simulator does not provide an exact replica of flow in and production from a reservoir at least in part because the description of the reservoir and the boundary conditions for the equations for flow in a porous rock are generally known with an amount of uncertainty. Certain types of physical phenomena occur at a spatial scale that can be relatively small compared to size of a field. A balance can be struck between model scale and computational resources that results in model cell sizes being of the order of meters; rather than a lesser size (e.g., a level of detail of pores). A modeling and simulation workflow for multiphase flow in porous media (e.g., reservoir rock, etc.) can include generalizing real micro-scale data from macro scale observations (e.g., seismic data and well data) and upscaling to a manageable scale and problem size. Uncertainties can exist in input data and solution procedure such that simulation results too are to some extent uncertain. A process known as history matching can involve comparing simulation results to actual field data acquired during production of fluid from a field. Information gleaned from history matching, can provide for adjustments to a model, data, etc., which can help to increase accuracy of simulation.

In an example embodiment, the simulation component 120 may include accessing entities 122. Entities 122 may include earth entities or geological objects such as wells, surfaces, reservoirs, etc. In the system 100, the entities 122 can include virtual representations of actual physical entities that may be reconstructed for purposes of simulation. The entities 122 may include entities based on data acquired via sensing, observation, etc. (e.g., consider entities based at least in part on the seismic data 112 and/or other information 114). As an example, an entity may be characterized by one or more properties (e.g., a geometrical pillar grid entity of an earth model may be characterized by a porosity property, etc.). Such properties may represent one or more measurements (e.g., acquired data), calculations, etc.

In an example embodiment, the simulation component 120 may operate in conjunction with a software framework such as an object-based framework. In such a framework, entities may include entities based on pre-defined classes to facilitate modeling and simulation. An example of an object-based framework is the MICROSOFT .NET framework (Redmond, Wash.), which provides a set of extensible object classes. In the .NET framework, an object class encapsulates a module of reusable code and associated data structures. Object classes can be used to instantiate object instances for use by a program, script, etc. For example, borehole classes may define objects for representing boreholes based on well data. A model of a basin, a reservoir, etc. may include one or more boreholes where a borehole may be, for example, for measurements, injection, production, etc. As an example, a borehole may be a wellbore of a well, which may be a completed well (e.g., for production of a resource from a reservoir, for injection of material, etc.).

In the example of FIG. 1, the simulation component 120 may process information to conform to one or more attributes specified by the attribute component 130, which may include a library of attributes (e.g., consider a library that includes seismic attributes, etc.). Such processing may occur prior to input to the simulation component 120 (e.g., consider the processing component 116). As an example, the simulation component 120 may perform operations on input information based on one or more attributes specified by the attribute component 130. In an example embodiment, the simulation component 120 may construct one or more models of the geologic environment 150, which may be utilized to simulate behavior of the geologic environment 150 (e.g., responsive to one or more acts, whether natural or artificial). In the example of FIG. 1, the analysis/visualization component 142 may allow for interaction with a model or model-based results (e.g., simulation results, etc.). As an example, output from the simulation component 120 may be input to one or more other workflows, as indicated by a workflow component 144.

As an example, the simulation component 120 may include one or more features of a simulator such as, for example, the ECLIPSE reservoir simulator (Schlumberger Limited, Houston Tex.), the INTERSECT reservoir simulator (Schlumberger Limited, Houston Tex.), the VISAGE geomechanics simulator (Schlumberger Limited, Houston Tex.), the PETROMOD petroleum systems simulator (Schlumberger Limited, Houston Tex.), the PIPESIM network simulator (Schlumberger Limited, Houston Tex.), etc.

The ECLIPSE simulator includes numerical solvers that may provide simulation results such as, for example, results that may predict dynamic behavior for one or more types of reservoirs, may assist with one or more development schemes, may assist with one or more production schemes, etc. The VISAGE simulator includes finite element numerical solvers that may provide simulation results such as, for example, results as to compaction and subsidence of a geologic environment, well and completion integrity in a geologic environment, cap-rock and fault-seal integrity in a geologic environment, fracture behavior in a geologic environment, thermal recovery in a geologic environment, CO2 disposal, etc. The PETROMOD simulator includes finite element numerical solvers that may provide simulations results such as, for example, results as to structural evolution, temperature, and pressure history and as to effects of such factors on generation, migration, accumulation, and loss of oil and gas in a petroleum system through geologic time. Such a simulator can provide properties such as, for example, gas/oil ratios (GOR) and API gravities, which may be analyzed, understood, and predicted as to a geologic environment. The PIPESIM simulator includes solvers that may provide simulation results such as, for example, multiphase flow results (e.g., from a reservoir to a wellhead and beyond, etc.), flowline and surface facility performance, etc. The PIPESIM simulator may be integrated, for example, with the AVOCET production operations framework (Schlumberger Limited, Houston Tex.). As an example, a reservoir or reservoirs may be simulated with respect to one or more enhanced recovery techniques (e.g., consider a thermal process such as steam-assisted gravity drainage (SAGD), etc.). As an example, the PIPESIM simulator may be an optimizer that can optimize one or more operational scenarios at least in part via simulation of physical phenomena.

In an example embodiment, the management components 110 may include features of a framework such as the PETREL seismic to simulation software framework (Schlumberger Limited, Houston, Tex.). The PETREL framework provides components that allow for optimization of exploration and development operations. The PETREL framework includes seismic to simulation software components that can output information for use in increasing reservoir performance, for example, by improving asset team productivity. Through use of such a framework, various professionals (e.g., geophysicists, geologists, and reservoir engineers) can develop collaborative workflows and integrate operations to streamline processes (e.g., with respect to one or more geologic environments, etc.). Such a framework may be considered an application (e.g., executable using one or more devices) and may be considered a data-driven application (e.g., where data is input for purposes of modeling, simulating, etc.).

In an example embodiment, various aspects of the management components 110 may include add-ons or plug-ins that operate according to specifications of a framework environment. For example, a framework environment marketed as the OCEAN framework environment (Schlumberger Limited, Houston, Tex.) allows for integration of add-ons (or plug-ins) into a PETREL framework workflow. The OCEAN framework environment leverages .NET tools (Microsoft Corporation, Redmond, Wash.) and offers stable, user-friendly interfaces for efficient development. In an example embodiment, various components may be implemented as add-ons (or plug-ins) that conform to and operate according to specifications of a framework environment (e.g., according to application programming interface (API) specifications, etc.).

FIG. 1 also shows an example of a framework 170 that includes a model simulation layer 180 along with a framework services layer 190, a framework core layer 195 and an instructions layer 175. As an example, the instructions layer 175 can include various sets of instructions that may be stored in a computer-readable storage medium or media where the instructions can be executable by one or more processors to instruct a computing device, a computing system, etc. to perform one or more operations. As an example, a component may be or include a set of instructions or sets of instructions.

In the example of FIG. 1, the framework 170 may include the OCEAN framework where the model simulation layer 180 is the PETREL model-centric software package that hosts OCEAN framework applications. In an example embodiment, the PETREL software may be considered a data-driven application. The PETREL software can include a framework for model building and visualization. Such a model may include one or more grids.

As an example, a framework may be implemented within or in a manner operatively coupled to the DELFI cognitive exploration and production (E&P) environment (Schlumberger, Houston, Tex.), which is a secure, cognitive, cloud-based collaborative environment that integrates data and workflows with digital technologies, such as artificial intelligence and machine learning. As an example, such an environment can provide for operations that involve one or more frameworks. The DELFI environment may be referred to as the DELFI framework, which may be a framework of frameworks. As an example, the DELFI framework can include various other frameworks, which can include, for example, one or more types of models (e.g., simulation models, etc.).

The model simulation layer 180 may provide domain objects 182, act as a data source 184, provide for rendering 186 and provide for various user interfaces 188. Rendering 186 may provide a graphical environment in which applications can display their data while the user interfaces 188 may provide a common look and feel for application user interface components. As an example, a user interface may be a graphical user interface (GUI) that can be rendered to a display, via a virtual reality (VR) system, etc. As an example, a VR system may include one or more features of a VR system such as, for example, the HOLOLENS VR system marketed by Microsoft Corporation (Redmond, Wash.). For example, a VR system may include goggles and/or one or more other types of wearables that can facilitate generation of and/or interaction with a virtual environment.

In the example of FIG. 1, the domain objects 182 can include entity objects, property objects and optionally other objects. Entity objects may be used to geometrically represent wells, surfaces, reservoirs, etc., while property objects may be used to provide property values as well as data versions and display parameters. For example, an entity object may represent a well where a property object provides log information as well as version information and display information (e.g., to display the well as part of a model).

In the example of FIG. 1, data may be stored in one or more data sources (or data stores, generally physical data storage devices), which may be at the same or different physical sites and accessible via one or more networks. As an example, the model simulation layer 180 may be configured to model projects. As such, a particular project may be stored where stored project information may include inputs, models, results and cases. As an example, upon completion of a modeling session, a user may store a project. In such an example, at a later time, the project may be accessed and restored using the model simulation layer 180, which can recreate instances of the relevant domain objects.

In the example of FIG. 1, the geologic environment 150 may include layers (e.g., stratification) that include a reservoir 151 and that may be intersected by a fault 153. As an example, the geologic environment 150 may be outfitted with any of a variety of sensors, detectors, actuators, etc. For example, equipment 152 may include communication circuitry to receive and to transmit information with respect to one or more networks 155. Such information may include information associated with downhole equipment 154, which may be equipment to acquire information, to assist with resource recovery, etc. Other equipment 156 may be located remote from a well site and include sensing, detecting, emitting or other circuitry. Such equipment may include storage and communication circuitry to store and to communicate data, instructions, etc. As an example, one or more satellites may be provided for purposes of communications, data acquisition, etc. For example, FIG. 1 shows a satellite in communication with the network 155 that may be configured for communications, noting that the satellite may additionally or alternatively include circuitry for imagery (e.g., spatial, spectral, temporal, radiometric, etc.).

FIG. 1 also shows the geologic environment 150 as optionally including equipment 157 and 158 associated with a well that includes a substantially horizontal portion that may intersect with the one or more fractures 159. For example, consider a well in a shale formation that may include natural fractures, artificial fractures (e.g., hydraulic fractures) or a combination of natural and artificial fractures. As an example, a well may be drilled for a reservoir that is laterally extensive. In such an example, lateral variations in properties, stresses, etc. may exist where an assessment of such variations may assist with planning, operations, etc. to develop a laterally extensive reservoir (e.g., via fracturing, injecting, extracting, etc.). As an example, the equipment 157 and/or 158 may include components, a system, systems, etc. for fracturing, seismic sensing, analysis of seismic data, assessment of one or more fractures, etc.

As mentioned, the system 100 may be used to perform one or more workflows. A workflow may be a process that includes a number of worksteps. A workstep may operate on data, for example, to create new data, to update existing data, etc. As an example, a may operate on one or more inputs and create one or more results, for example, based on one or more algorithms. As an example, a system may include a workflow editor for creation, editing, executing, etc. of a workflow. In such an example, the workflow editor may provide for selection of one or more pre-defined worksteps, one or more customized worksteps, etc. As an example, a workflow may be a workflow implementable in the PETREL framework, for example, that operates on seismic data, seismic attribute(s), etc. As an example, a workflow may be a process implementable in the OCEAN framework. As an example, a workflow may include one or more worksteps that access instructions such as instructions of a plug-in (e.g., external executable code, etc.).

FIG. 1 also shows instructions 198, which may operate in conjunction with the framework 170. For example, the instructions 198 may be implemented as one or more plug-ins, one or more external sets of instructions, one or more components, etc. As an example, the instructions 198 may include sets of instructions associated with the TECHLOG framework (Schlumberger Limited, Houston, Tex.), which can provide wellbore-centric, cross-domain workflows based on a data management layer. The TECHLOG framework includes features for petrophysics (core and log), geology, drilling, reservoir and production engineering, and geophysics. As an example, data received via the TECHLOG framework may be utilized by one or more inversion algorithms, which may aim to generate spatially distributed properties of a subterranean environment.

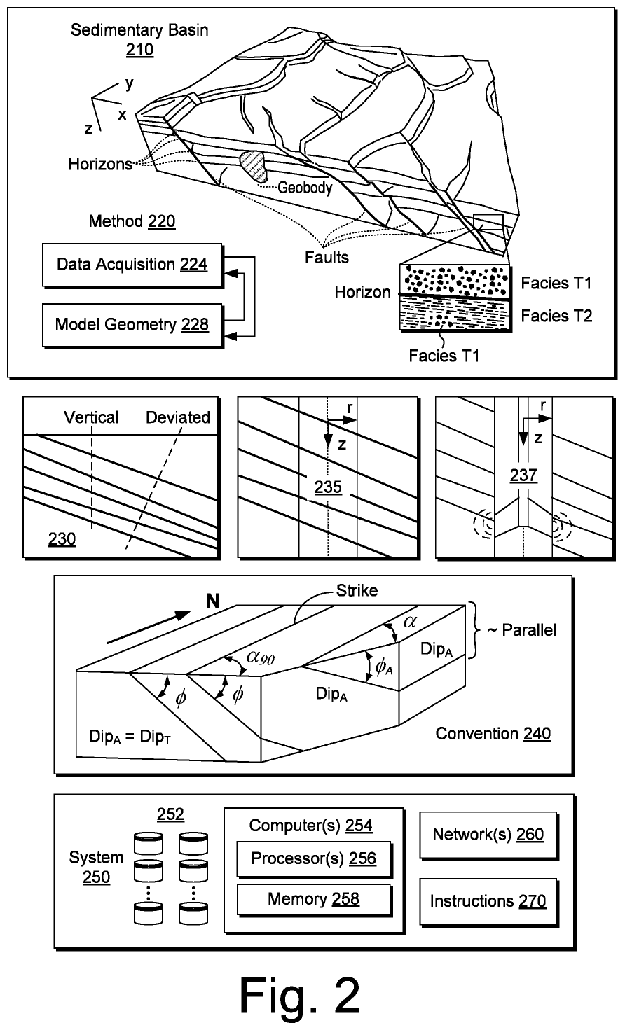

FIG. 2 shows an example of a sedimentary basin 210 (e.g., a geologic environment), an example of a method 220 for model building (e.g., for a simulator, etc.), an example of a formation 230, an example of a borehole 235 in a formation, an example of a convention 240 and an example of a system 250.

As an example, data acquisition, reservoir simulation, petroleum systems modeling, etc. may be applied to characterize various types of subsurface environments, including environments such as those of FIG. 1.

In FIG. 2, the sedimentary basin 210, which is a geologic environment, includes horizons, faults, one or more geobodies and facies formed over some period of geologic time. These features are distributed in two or three dimensions in space, for example, with respect to a Cartesian coordinate system (e.g., x, y and z) or other coordinate system (e.g., cylindrical, spherical, etc.). As shown, the model building method 220 includes a data acquisition block 224 and a model geometry block 228. Some data may be involved in building an initial model and, thereafter, the model may optionally be updated in response to model output, changes in time, physical phenomena, additional data, etc. As an example, data for modeling may include one or more of the following: depth or thickness maps and fault geometries and timing from seismic, remote-sensing, electromagnetic, gravity, outcrop and well log data. Furthermore, data may include depth and thickness maps stemming from facies variations (e.g., due to seismic unconformities) assumed to following geological events (“iso” times) and data may include lateral facies variations (e.g., due to lateral variation in sedimentation characteristics).

To proceed to modeling of geological processes, data may be provided, for example, data such as geochemical data (e.g., temperature, kerogen type, organic richness, etc.), timing data (e.g., from paleontology, radiometric dating, magnetic reversals, rock and fluid properties, etc.) and boundary condition data (e.g., heat-flow history, surface temperature, paleowater depth, etc.).

In basin and petroleum systems modeling, quantities such as temperature, pressure and porosity distributions within the sediments may be modeled, for example, by solving partial differential equations (PDEs) using one or more numerical techniques. Modeling may also model geometry with respect to time, for example, to account for changes stemming from geological events (e.g., deposition of material, erosion of material, shifting of material, etc.).

The aforementioned modeling framework marketed as the PETROMOD framework (Schlumberger Limited, Houston, Tex.) includes features for input of various types of information (e.g., seismic, well, geological, etc.) to model evolution of a sedimentary basin. The PETROMOD framework provides for petroleum systems modeling via input of various data such as seismic data, well data and other geological data, for example, to model evolution of a sedimentary basin. The PETROMOD framework may predict if, and how, a reservoir has been charged with hydrocarbons, including, for example, the source and timing of hydrocarbon generation, migration routes, quantities, pore pressure and hydrocarbon type in the subsurface or at surface conditions. In combination with a framework such as the PETREL framework, workflows may be constructed to provide basin-to-prospect scale exploration solutions. Data exchange between frameworks can facilitate construction of models, analysis of data (e.g., PETROMOD framework data analyzed using PETREL framework capabilities), and coupling of workflows. As an example, the TECHLOG framework may be implemented in a workflow, for example, using one or more features for petrophysics (core and log), geology, drilling, reservoir and production engineering, and geophysics.

As shown in FIG. 2, the formation 230 includes a horizontal surface and various subsurface layers. As an example, a borehole may be vertical. As another example, a borehole may be deviated. In the example of FIG. 2, the borehole 235 may be considered a vertical borehole, for example, where the z-axis extends downwardly normal to the horizontal surface of the formation 230. As an example, a tool 237 may be positioned in a borehole, for example, to acquire information. As mentioned, a borehole tool can include one or more sensors that can acquire borehole images via one or more imaging techniques. A data acquisition sequence for such a tool can include running the tool into a borehole with acquisition pads closed, opening and pressing the pads against a wall of the borehole, delivering electrical current into the material defining the borehole while translating the tool in the borehole, and sensing current remotely, which is altered by interactions with the material.

As an example, data can include geochemical data. For example, consider data acquired using X-ray fluorescence (XRF) technology, Fourier transform infrared spectroscopy (FTIR) technology and/or wireline geochemical technology.

As an example, one or more probes may be deployed in a bore via a wireline or wirelines. As an example, a probe may emit energy and receive energy where such energy may be analyzed to help determine mineral composition of rock surrounding a bore. As an example, nuclear magnetic resonance may be implemented (e.g., via a wireline, downhole NMR probe, etc.), for example, to acquire data as to nuclear magnetic properties of elements in a formation (e.g., hydrogen, carbon, phosphorous, etc.).

As an example, lithology scanning technology may be employed to acquire and analyze data. For example, consider the LITHO SCANNER technology marketed by Schlumberger Limited (Houston, Tex.). As an example, a LITHO SCANNER tool may be a gamma ray spectroscopy tool.

As an example, a tool may be positioned to acquire information in a portion of a borehole. Analysis of such information may reveal vugs, dissolution planes (e.g., dissolution along bedding planes), stress-related features, dip events, etc. As an example, a tool may acquire information that may help to characterize a fractured reservoir, optionally where fractures may be natural and/or artificial (e.g., hydraulic fractures). Such information may assist with completions, stimulation treatment, etc. As an example, information acquired by a tool may be analyzed using a framework such as the aforementioned TECHLOG framework (Schlumberger Limited, Houston, Tex.).

As an example, a workflow may utilize one or more types of data for one or more processes (e.g., stratigraphic modeling, basin modeling, completion designs, drilling, production, injection, etc.). As an example, one or more tools may provide data that can be used in a workflow or workflows that may implement one or more frameworks (e.g., PETREL, TECHLOG, PETROMOD, etc.).

As to the convention 240 for dip, as shown in FIG. 2, the three dimensional orientation of a plane can be defined by its dip and strike. Dip is the angle of slope of a plane from a horizontal plane (e.g., an imaginary plane) measured in a vertical plane in a specific direction. Dip may be defined by magnitude (e.g., also known as angle or amount) and azimuth (e.g., also known as direction). As shown in the convention 240 of FIG. 2, various angles θ indicate angle of slope downwards, for example, from an imaginary horizontal plane (e.g., flat upper surface); whereas, dip refers to the direction towards which a dipping plane slopes (e.g., which may be given with respect to degrees, compass directions, etc.). Another feature shown in the convention of FIG. 2 is strike, which is the orientation of the line created by the intersection of a dipping plane and a horizontal plane (e.g., consider the flat upper surface as being an imaginary horizontal plane).

Some additional terms related to dip and strike may apply to an analysis, for example, depending on circumstances, orientation of collected data, etc. One term is “true dip” (see, e.g., Dip_{T} in the convention 240 of FIG. 2). True dip is the dip of a plane measured directly perpendicular to strike (see, e.g., line directed northwardly and labeled “strike” and angle α₉₀) and also the maximum possible value of dip magnitude. Another term is “apparent dip” (see, e.g., Dip_{A} in the convention 240 of FIG. 2). Apparent dip may be the dip of a plane as measured in any other direction except in the direction of true dip (see, e.g., ϕ_{A} as Dip_{A} for angle α); however, it is possible that the apparent dip is equal to the true dip (see, e.g., ϕ as Dip_{A}=Dip_{T} for angle α₉₀ with respect to the strike). In other words, where the term apparent dip is used (e.g., in a method, analysis, algorithm, etc.), for a particular dipping plane, a value for “apparent dip” may be equivalent to the true dip of that particular dipping plane.

As shown in the convention 240 of FIG. 2, the dip of a plane as seen in a cross-section perpendicular to the strike is true dip (see, e.g., the surface with ϕ as Dip_{A}=Dip_{T} for angle α₉₀ with respect to the strike). As indicated, dip observed in a cross-section in any other direction is apparent dip (see, e.g., surfaces labeled Dip_{A}). Further, as shown in the convention 240 of FIG. 2, apparent dip may be approximately 0 degrees (e.g., parallel to a horizontal surface where an edge of a cutting plane runs along a strike direction).

In terms of observing dip in wellbores, true dip is observed in wells drilled vertically. In wells drilled in any other orientation (or deviation), the dips observed are apparent dips (e.g., which are referred to by some as relative dips). In order to determine true dip values for planes observed in such boreholes, as an example, a vector computation (e.g., based on the borehole deviation) may be applied to one or more apparent dip values.

As mentioned, another term that finds use in sedimentological interpretations from borehole images is “relative dip” (e.g., Dip_{R}). A value of true dip measured from borehole images in rocks deposited in very calm environments may be subtracted (e.g., using vector-subtraction) from dips in a sand body. In such an example, the resulting dips are called relative dips and may find use in interpreting sand body orientation.

A convention such as the convention 240 may be used with respect to an analysis, an interpretation, an attribute, etc. (see, e.g., various blocks of the system 100 of FIG. 1). As an example, various types of features may be described, in part, by dip (e.g., sedimentary bedding, faults and fractures, cuestas, igneous dikes and sills, metamorphic foliation, etc.). As an example, dip may change spatially as a layer approaches a geobody. For example, consider a salt body that may rise due to various forces (e.g., buoyancy, etc.). In such an example, dip may trend upward as a salt body moves upward.

Seismic interpretation may aim to identify and/or classify one or more subsurface boundaries based at least in part on one or more dip parameters (e.g., angle or magnitude, azimuth, etc.). As an example, various types of features (e.g., sedimentary bedding, faults and fractures, cuestas, igneous dikes and sills, metamorphic foliation, etc.) may be described at least in part by angle, at least in part by azimuth, etc.

As an example, equations may be provided for petroleum expulsion and migration, which may be modeled and simulated, for example, with respect to a period of time. Petroleum migration from a source material (e.g., primary migration or expulsion) may include use of a saturation model where migration-saturation values control expulsion. Determinations as to secondary migration of petroleum (e.g., oil or gas), may include using hydrodynamic potential of fluid and accounting for driving forces that promote fluid flow. Such forces can include buoyancy gradient, pore pressure gradient, and capillary pressure gradient.

As shown in FIG. 2, the system 250 includes one or more information storage devices 252, one or more computers 254, one or more networks 260 and instructions 270. As to the one or more computers 254, each computer may include one or more processors (e.g., or processing cores) 256 and memory 258 for storing instructions, for example, consider the instructions 270 as including instructions executable by at least one of the one or more processors. As an example, a computer may include one or more network interfaces (e.g., wired or wireless), one or more graphics cards (e.g., one or more GPUs, etc.), a display interface (e.g., wired or wireless), etc. As an example, imagery such as surface imagery (e.g., satellite, geological, geophysical, etc.) may be stored, processed, communicated, etc. As an example, data may include SAR data, GPS data, etc. and may be stored, for example, in one or more of the storage devices 252.

As an example, the instructions 270 may include instructions (e.g., stored in memory) executable by one or more processors to instruct the system 250 to perform various actions. As an example, the system 250 may be configured such that the instructions 270 provide for establishing the framework 170 of FIG. 1 or a portion thereof. As an example, one or more methods, techniques, etc. may be performed at least in part via instructions, which may be, for example, instructions of the instructions 270 of FIG. 2.

As an example, a framework can include various components. For example, a framework can include one or more components for prediction of reservoir performance, one or more components for optimization of an operation or operations, one or more components for control of production engineering operations, etc. As an example, a framework can include components for prediction of reservoir performance, optimization and control of production engineering operations performed at one or more reservoir wells. Such a framework may, for example, allow for implementation of various methods. For example, consider an approach that allows for a combination of physics-based and data-driven methods for modeling and forecasting a reservoir production.

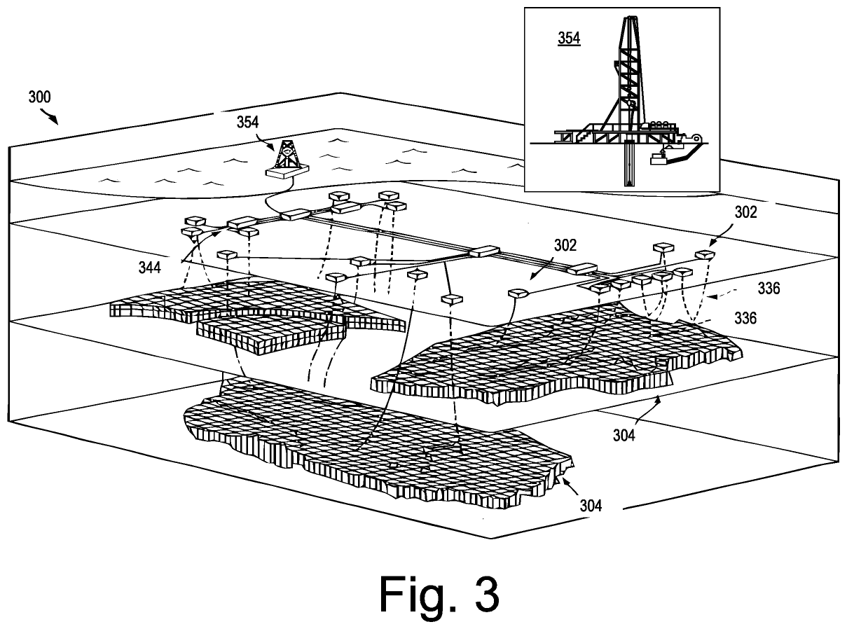

FIG. 3 shows an example of a geologic environment 300 as including various types of equipment and features. As shown, the geologic environment 300 includes a plurality of wellsites 302 operatively connected to a processing facility 354. In the example of FIG. 3, individual wellsites 302 can include equipment that can form individual wellbores 336 (e.g., rigs, etc.). Such wellbores can extend through subterranean formations 306 including one or more reservoirs 304. Such reservoirs 304 can include fluids, such as hydrocarbons. As an example, wellsites can draw fluid from one or more reservoirs and pass them to one or more processing facilities via one or more surface networks 344. As an example, a surface network can include tubing and control mechanisms for controlling flow of fluids from a wellsite to a processing facility.

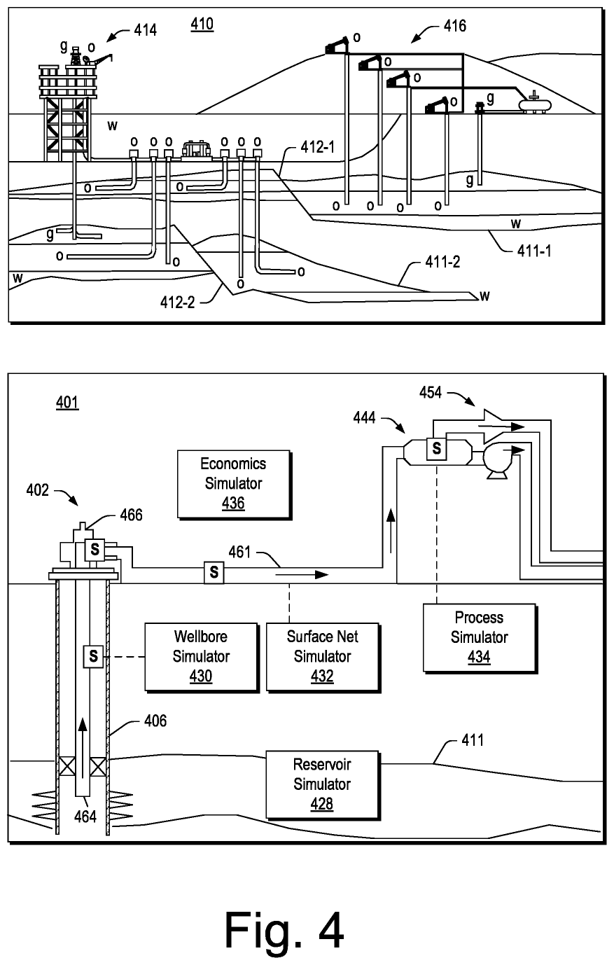

FIG. 4 shows an example of portion of a geologic environment 401 and an example of a larger portion of a geologic environment 410. As shown, a geologic environment can include one or more reservoirs 1411-1 and 411-2, which may be faulted by faults 412-1 and 412-2. FIG. 4 also shows some examples of offshore equipment 414 for oil and gas operations related to the reservoirs 411-1 and 411-2 and onshore equipment 416 for oil and gas operations related to the reservoir 1411-1. As an example, a system may be implemented for operations associated with one or more of such reservoirs.

As to the geologic environment 401, FIG. 4 shows a schematic view where the geologic environment 401 can include various types of equipment. As shown in FIG. 4, the environment 401 can includes a wellsite 402 and a fluid network 444. The wellsite 402 includes a wellbore 406 extending into earth as completed and prepared for production of fluid from a reservoir 411.

In the example of FIG. 4, wellbore production equipment 464 extends from a wellhead 466 of the wellsite 402 and to the reservoir 411 to draw fluid to the surface. As shown, the wellsite 402 is operatively connected to the fluid network 444 via a transport line 461. As indicated by various arrows, fluid can flow from the reservoir 411, through the wellbore 406 and onto the fluid network 444. Fluid can then flow from the fluid network 444, for example, to one or more fluid processing facilities.

In the example of FIG. 4, sensors (S) are located, for example, to monitor various parameters during operations. The sensors (S) may measure, for example, pressure, temperature, flowrate, composition, and other parameters of the reservoir, wellbore, gathering network, process facilities and/or other portions of an operation. As an example, the sensors (S) may be operatively connected to a surface unit (e.g., to instruct the sensors to acquire data, to collect data from the sensors, etc.).

In the example of FIG. 4, a surface unit can include computer facilities, such as a memory device, a controller, one or more processors, and display unit (e.g., for managing data, visualizing results of an analysis, etc.). As an example, data may be collected in the memory device and processed by the processor(s) (e.g., for analysis, etc.). As an example, data may be collected from the sensors (S) and/or by one or more other sources. For example, data may be supplemented by historical data collected from other operations, user inputs, etc. As an example, analyzed data may be used to in a decision making process.

As an example, a transceiver may be provided to allow communications between a surface unit and one or more pieces of equipment in the environment 401. For example, a controller may be used to actuate mechanisms in the environment 401 via the transceiver, optionally based on one or more decisions of a decision making process. In such a manner, equipment in the environment 401 may be selectively adjusted based at least in part on collected data. Such adjustments may be made, for example, automatically based on computer protocol, manually by an operator or both. As an example, one or more well plans may be adjusted (e.g., to select optimum operating conditions, to avoid problems, etc.).

To facilitate data analyses, one or more simulators may be implemented (e.g., optionally via the surface unit or other unit, system, etc.). As an example, data fed into one or more simulators may be historical data, real time data or combinations thereof. As an example, simulation through one or more simulators may be repeated or adjusted based on the data received.

In the example of FIG. 4, simulators can include a reservoir simulator 428, a wellbore simulator 430, a surface network simulator 432, a process simulator 434 and an economics simulator 436. As an example, the reservoir simulator 428 may be configured to solve for hydrocarbon flow rate through a reservoir and into one or more wellbores. As an example, the wellbore simulator 430 and surface network simulator 432 may be configured to solve for hydrocarbon flow rate through a wellbore and a surface gathering network of pipelines. As to the process simulator 434, it may be configured to model a processing plant where fluid containing hydrocarbons is separated into its constituent components (e.g., methane, ethane, propane, etc.), for example, and prepared for further distribution (e.g., transport via road, rail, pipe, etc.) and optionally sale. As an example, the economics simulator 436 may be configured to model costs associated with at least part of an operation. For example, consider MERAK framework (Schlumberger Limited, Houston, Tex.), which may provide for economic analyses.

As an example, a system can include and/or be operatively coupled to one or more of the simulators 428, 430, 432, 434 and 436 of FIG. 4. As an example, such simulators may be associated with frameworks and/or may be considered tools.

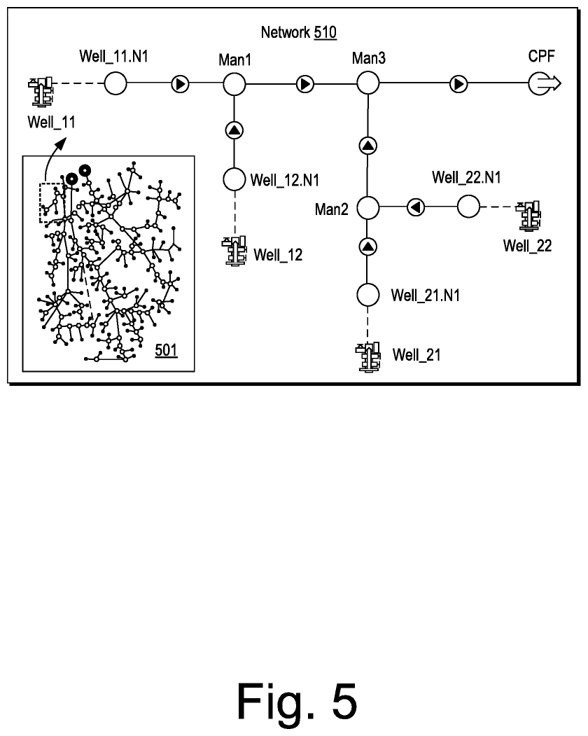

FIG. 5 shows an example of a network 501 and a detailed portion 510, which can also be considered to be a network (e.g., network 510). As shown, a network can include a plurality of wells, for example, the network 510 includes a well 11, a well 12, a well 21 and a well 22. As shown, a network can include manifolds such as the manifolds labeled Man1, Man2, and Man3 in the network 510. Various conduits can be utilized for transport of fluid in a network, for example, from one or more wells to one or more processing facilities, optionally via one or more chokes, manifolds, pumps, etc. FIG. 5 shows that a network can be quite complex and include tens of wells or more.

A choke can be a device incorporating an orifice that is used to control fluid flow rate or downstream system pressure. Chokes may be available in various configurations, for example, for one or more of fixed and adjustable modes of operation. As an example, an adjustable choke may enable fluid flow and pressure parameters to be changed to suit process or production requirements, optionally via a controller that is operatively coupled to an actuator that can adjust one or more pieces of the choke. As to a fixed choke, it may be more resistant to erosion under prolonged operation or production of abrasive fluids than various adjustable chokes. As an example, a well may be fitted with a choke that can be selected and/or controlled to suit desired operational parameters (e.g., flow rate, production, etc.).

As an example, one or more artificial lift processes may be utilized in one or more field operations. Artificial lift can include, for example, a surface pump (e.g., a sucker rod pump), a downhole pump (e.g., an electric submersible pump), gas lift, etc. As an example, a network such as the network 501 of FIG. 5 can include one or more pieces of artificial lift equipment.

As to gas lift, it is a process where, for example, gas may be injected from an annulus into tubing. An annulus, as applied to an oil well or other well for recovering a subsurface resource may refer to a space, lumen, or void between piping, tubing or casing and the piping, tubing, or casing immediately surrounding it, for example, at a greater radius.

As an example, injected gas may aerate well fluid in production tubing in a manner that “lightens” the well fluid such that the fluid can flow more readily to a surface location. As an example, one or more gas lift valves may be configured to control flow of gas during an intermittent flow or a continuous flow gas lift operation. As an example, a gas lift valve may operate based at least in part on a differential pressure control that can actuate a valve mechanism of the gas lift valve.

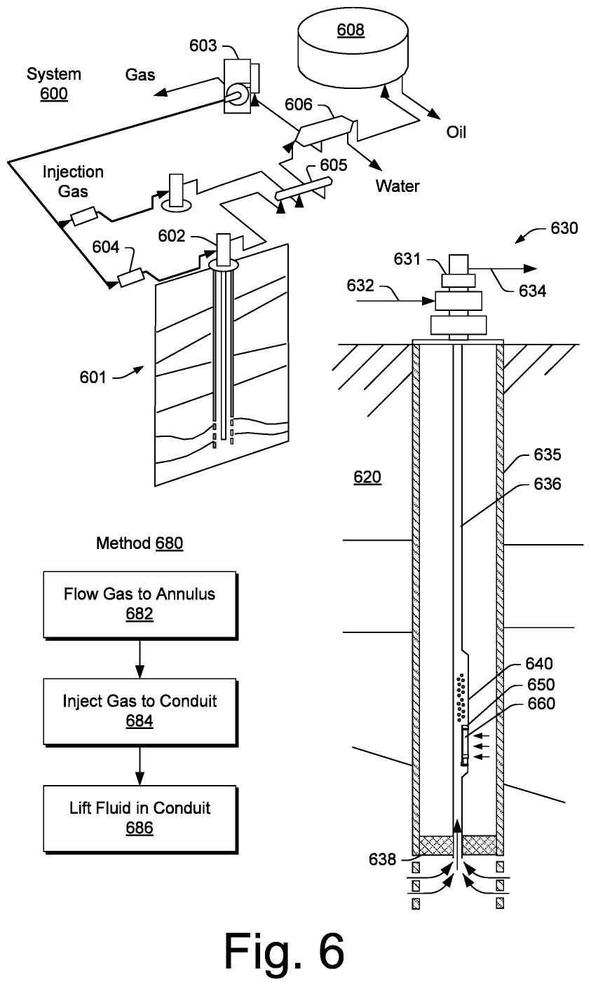

FIG. 6 shows an example of a system 600, an example of a geologic environment 620 that includes equipment and an example of a method 680. The system 600 includes a subterranean formation 601 with a well 602. Injection gas is provided to the well 602 via a compressor 603 and a regulator 604. The injection gas can assist with lifting fluid that flows from the subterranean formation 601 to the well 602. The lifted fluid, including injected gas, may flow to a manifold 605, for example, where fluid from a number of wells may be combined. As shown in the example of FIG. 6, the manifold 605 is operatively coupled to a separator 606, which may separate components of the fluid. For example, the separator 606 may separate oil, water and gas components as substantially separate phases of a multiphase fluid. In such an example, oil may be directed to an oil storage facility 608 while gas may be directed to the compressor 603, for example, for re-injection, storage and/or transport to another location. As an example, water may be directed to a water discharge, a water storage facility, etc.

As shown in FIG. 6, the geologic environment 620 is fitted with well equipment 630, which includes a well-head 631 (e.g., a Christmas tree, etc.), an inlet conduit 632 for flow of compressed gas, an outlet conduit 634 for flow of produced fluid, a casing 635, a production conduit 636, and a packer 638 that forms a seal between the casing 635 and the production conduit 636. As shown, fluid may enter the casing 635 (e.g., via perforations) and then enter a lumen of the production conduit 636, for example, due to a pressure differential between the fluid in the subterranean geologic environment 620 and the lumen of the production conduit 636 at an opening of the production conduit 636. Where the inlet conduit 632 for flow of compressed gas is used to flow gas to the annular space between the casing 635 and the production conduit 636, a mandrel 640 operatively coupled to the production conduit 636 that includes a pocket 650 that seats a gas lift valve 660 that may regulate the introduction of the compressed gas into the lumen of the production conduit 636. In such an example, the compressed gas introduced may facilitate flow of fluid upwardly to the well-head 631 (e.g., opposite a direction of gravity) where the fluid may be directed away from the well-head 631 via the outlet conduit 634.

As shown in FIG. 6, the method 680 can include a flow block 682 for flowing gas to an annulus (e.g., or, more generally, a space exterior to a production conduit fitted with a gas lift valve), an injection block 684 for injecting gas from the annulus into a production conduit via a gas lift valve or gas lift valves and a lift block 686 for lifting fluid in the production conduit due in part to buoyancy imparted by the injected gas.

As an example, where a gas lift valve includes one or more actuators where such actuators may optionally be utilized to control, at least in part, operation of a gas lift valve (e.g., one or more valve members of a gas lift valve). As an example, surface equipment can include one or more control lines that may be operatively coupled to a gas lift valve or gas lift valves, for example, where a gas lift valve may respond to a control signal or signals via the one or more control lines. As an example, surface equipment can include one or more power lines that may be operatively coupled to a gas lift valve or gas lift valves, for example, where a gas lift valve may respond to power delivered via the one or more power lines. As an example, a system can include one or more control lines and one or more power lines where, for example, a line may be a control line, a power line or a control and power line.

As an example, a production process may optionally utilize one or more fluid pumps such as, for example, an electric submersible pump (e.g., consider a centrifugal pump, a rod pump, etc.). As an example, a production process may implement one or more so-called “artificial lift” technologies. An artificial lift technology may operate by adding energy to fluid, for example, to initiate, enhance, etc. production of fluid.

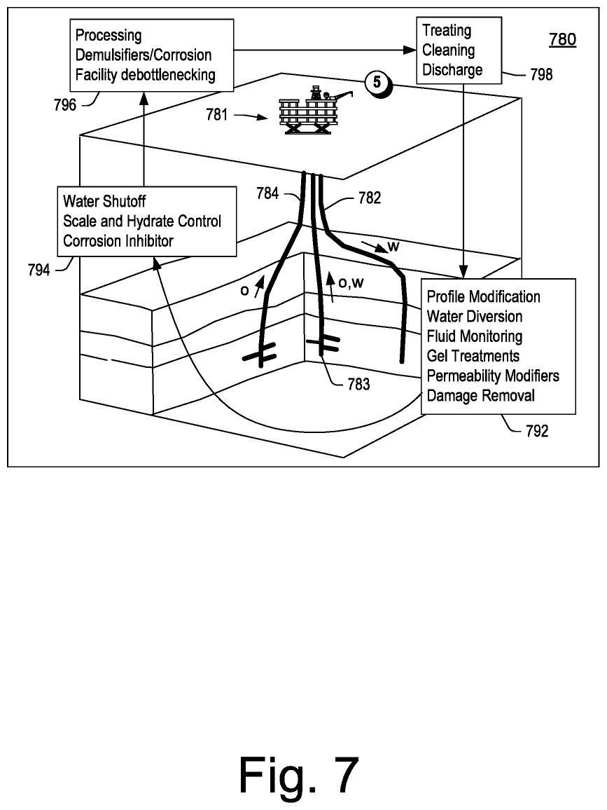

FIG. 7 shows an example of a site 780 includes equipment 781 for injection of water to enhance recovery of oil where an injection well for water 782, a production well for oil and water 783 and a production well for “dry oil” 784 (e.g., oil with a water fraction below a water fraction limit) are illustrated. The operations at the site 780 can form a water cycle that includes injecting water such that water is transported through the field with flow in a reservoir leading to production followed by surface processing. Surface processing can include separating water from a mixture of water and oil where the water may be disposed of at the surface or injected for disposal or pressure maintenance (e.g., for maintaining reservoir pressure). In a field, production efficiency for oil can be managed through effective control of water, which may be achieved via water-control services. Factors involved in water control include flow rate, production rate, fluid properties (e.g., oil gravity and water salinity), and disposal method. Operational factors include those associated with, for example, lifting, separation, filtering, pumping and reinjection. Costs as to water control per barrel of oil can range over a magnitude. Managing the cycle of water production (e.g., separation downhole or at surface, disposal, etc.) can involve a wide range of oilfield services, which can include data acquisition, diagnostics, production logging, water analysis, reservoir modeling (e.g., to characterize flow), and technologies to address water-related issues. A water-control plan can include setting-up equipment for detection of excess water and control of excess water once detected and/or once modeled to become an issue. During operations, one or more types of measurements may be made, optionally at different times, in response to different conditions (e.g., whether modeled and/or measured), etc.

In the example of FIG. 7, a water cycle is illustrated via blocks 792, 794, 796 and 798. The block 792 can represent one or more processes such as, for example, profile modification, water diversion, fluid monitoring, gel treatment(s), permeability modifier(s), and damage removal. The block 794 can represent one or more processes such as, for example, water shutoff, scale and hydrate control and corrosion inhibition. The block 796 can represent one or more processes such as processing of produced fluid, demulsification and/or corrosion-related fluid processing and facility debottlenecking. The block 798 can represent one or more processes such as treating fluid, cleaning fluid and discharging fluid where such fluid can be or include water.

As an example, a representation of the site 780 may be rendered to a display as part of a graphical user interface, which may be, for example, a rendered in part via a Web browser application executing on a client device with a network interface that is operatively coupled to the Internet and, for example, to a cloud environment. As an example, such a client device may be part of or operatively coupled to a client layer.

Data associated with the site 780 can include measured data and optionally synthetic data. For example, water flow may be modeled via a simulation model, which may be a dynamic simulation model that can receive information from a site during an injection operation and generate synthetic data in real-time or near real-time (e.g., of the order of minutes) that can be integrated into one or more analyses of a system.

A system may utilize such data to identify a time-dependent response of injected water to production of oil and/or an oil and water mixture. As an example, an increase in water fraction in production of an oil and water mixture may indicate that streamlining is occurring at a point in time during a planned injection schedule, which may, for example, be dynamically adjusted according to output from a system. A system may analyze water fraction and/or one or more other measurements and respond to changes in by outputting parameters that can directly or indirectly be utilized to control equipment at a site during an ongoing operation or operations. For example, injection rate of water may be adjusted via control of one or more pumps.

Water control can increase well productivity and the amount of oil produced from a reservoir. A well can have a lifetime where, as the well matures, the water/oil ratio (WOR) increases with production due to increasing amounts of water being produced by the well. Various costs are associated with production and can be characterized in part by the WOR (e.g., or water fraction). For example, at a particular WOR, the cost of handling water can approach the value of oil being produced. In such an example, that particular WOR can be a proxy for an “economic limit” that is based on physical realities of handling water in a field during oil production. Water control can be implemented to reduce a well's water production (e.g., reducing the well's WOR), which can help to maintain WOR below an economic limit as the well matures. A reduction in WOR during a well's lifetime can provide an added recovery period of time for the well where the WOR again rises toward the WOR representing the economic limit; noting that such a WOR as an economic limit can change over time due to one or more factors (e.g., price of oil per barrel, cost of water, cost of handling water, etc.).

As an example, a system may operate in one state that acts to model and simulate flow of water and oil in a reservoir and can operate in another state that acts to optimize processing of multiphase fluid that includes oil and water. As an example, a state can be an overarching state that includes the aforementioned two states where they can be linked to generate multiple outputs. Such outputs can include field development plan output as to production of oil, an optimal treatment scenario output as to injection and handling of water, an immediate action notice or advice output as to a water-related parameter and output as to adjustment of a reservoir model that is utilized to simulate fluid flow in the reservoir. Such a system can be operatively coupled to field equipment (e.g., sensors, controllers, etc.) and can be implemented at least in part via a cloud architecture such as the architecture.

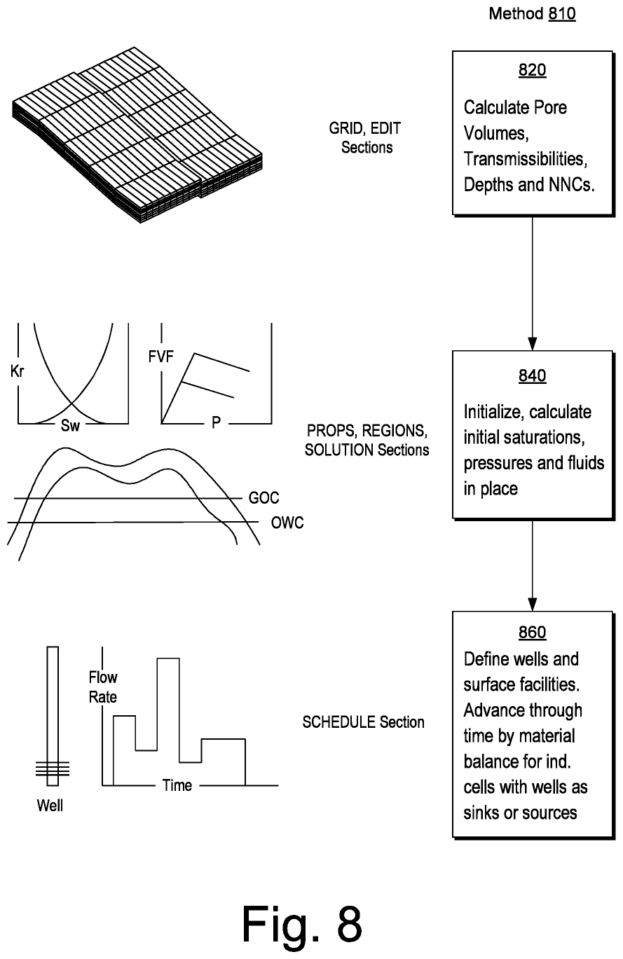

FIG. 8 shows an example of a method 810 that includes a calculation block 820 for calculating pore volumes, transmissibilities, depths and NNCs, an initialization and calculation block 840 for initializing and calculating initial saturations, pressure and fluids in place, and a definition and time progression block 860 for defining one or more wells and surface facilities and advancing through time, for example, via material balances for individual cells (e.g., with the one or more wells as individual sinks and/or sources).

As to the initialization and calculation block 840, for an initial time (e.g., to), saturation distribution within a grid model of a geologic environment and pressure distribution within the grid model of the geologic environment may be set to represent an equilibrium state (e.g., a static state or “no-flow” state), for example, with respect to gravity. As an example, to approximate the equilibrium state, calculations can be performed. As an example, such calculations may be performed by one or more sets of instructions. For example, one or more of a seismic-to-simulation framework, a reservoir simulator, a specialized set of instructions, etc. may be implemented to perform one or more calculations that may aim to approximate or to facilitate approximation of an equilibrium state. As an example, a reservoir simulator may include a set of instructions for initialization using data to compute capillary and fluid gradients, and hence fluid saturation densities in individual cells of a grid model that represents a geologic environment.

Initialization aims to define fluid saturations in individual cells such that a “system” being modeled is in an equilibrium state (e.g., where no external forces are applied, no fluid flow is to take place in a reservoir, a condition that may not be obeyed in practice). As an example, consider oil-water contact and assume no transition zone, for example, where water saturation is unity below an oil-water contact and at connate water saturation above the contact. In such an example, grid cells that include oil-water contact may pose some challenges. A cell (e.g., or grid cell) may represent a point or points in space for purposes of simulating a geologic environment. Where an individual cell represents a volume and where that individual cell includes, for example, a center point for definition of properties, within the volume of that individual cell, the properties may be constant (e.g., without variation within the volume). In such an example, that individual cell includes one value per property, for example, one value for water saturation. As an example, an initialization process can include selecting a value for individual properties of individual cells.

As an example, saturation distribution may be generated based on one or more types of information. For example, saturation distribution may be generated from seismic information and saturation versus depth measurements in one or more boreholes (e.g., test wells, wells, etc.). As an example, reproduction of such an initial saturation field via a simulation model may be inaccurate and such an initial saturation field may not represent an equilibrium state, for example, as a simulator model approximates real physical phenomena.

As an example, an initialization of water saturation may be performed using information as to oil-water contact. For example, for a cell that is below oil-water contact, a water saturation value for that cell may be set to unity (i.e., as water is the more dense phase, it is below the oil-water contact); and for a cell that is above oil-water contact, a water saturation value for that cell may be set to null (i.e., as oil is the lighter phase, it exists above water and hence is assumed to be free of water). Thus, in such an example, where at least some information as to spatially distributed depths of oil-water contact may be known, an initialized grid cell model may include cells with values of unity and cells with values of zero for water saturation.

As mentioned, an initialized grid cell model may not be in an equilibrium state. Thus, sets of instructions may be executed using a computing device, a computing system, etc. that acts to adjust an initialized grid cell model to approximate an equilibrium state. Given a certain saturation field for a grid cell model, a technique may adjust relative permeability end points (e.g., critical saturations) such that relevant fluids are just barely immobile at their calculated or otherwise defined initial saturations. As a result, the grid cell model, as initialized, may represent a quiescent state in the sense that no flow will occur if a simulation is started without application of some type of “force” (e.g., injection, production, etc.).

As mentioned, a reservoir simulator may advance in time. As an example, a numeric solver may be implemented that can generate a solution for individual time increments (e.g., points in time). As an example, a solver may implement an implicit solution scheme and/or an explicit solution scheme, noting that an implicit solution scheme may allow for larger time increments than an explicit scheme. Times at which a solution is desired may be set forth in a “schedule”. For example, a schedule may include smaller time increments for an earlier period of time followed by larger time increments.

A solver may implement one or more techniques to help assure stability, convergence, accuracy, etc. For example, when advancing a solution in time, a solver may implement sub-increments of time, however, an increase in the number of time increments can increase computation time. As an example, an adjustable increment size may be used, for example, based on information of one or more previous increments.

As an example, a simulator may implement an adjustable grid (or mesh) approach to help with stability, convergence, accuracy, etc. For example, when advancing a solution in time, a solver may implement grid refinement in a region where behavior may be changing, where a change in conditions exists/occurs, etc. For example, where a spatial gradient of a variable exceeds a threshold spatial gradient value, a re-gridding may be implement that refines the grid in the region by making grid cells smaller.

Adaptive gridding can help to decrease computational times of a simulator. Such a simulator may account for one or more types of physical phenomena, which can include concentrations, reactions, micelle formations, phase changes, thermal effects (e.g., introduction of heat energy, heat generated via reactions, heat consumed via reactions, etc.), momentum effects, pressure effects, etc. As an example, physical phenomena can be coupled via a system of equations of a simulator. One or more types of physical phenomena may be a trigger for adaptive gridding.

As an example, a numeric solver may implement one or more of a finite difference approach, a finite element approach, a finite volume approach, etc. As an example, the ECLIPSE reservoir simulator can implement central differences for spatial approximation and forward differences in time. As an example, a matrix that represents grid cells and associated equations may be sparse, diagonally banded and blocked as well as include off-diagonal entries.

As an example, a solver may implement an implicit pressure, explicit saturation (IMPES) scheme. Such a scheme may be considered to be an intermediate form of explicit and implicit techniques. In an IMPES scheme, saturations are updated explicitly while pressure is solved implicitly.

As to conservation of mass, saturation values (e.g., for water, gas and oil) in individual cells of a grid cell model may be specified to sum to unity, which may be considered a control criterion for mass conservation. In such an example, where the sum of saturations is not sufficiently close to unity, a process may be iterated until convergence is deemed satisfactory (e.g., according to one or more convergence criteria). As governing equations tend to be non-linear (e.g., compositional, black oil, etc.), a Newton-Raphson type of technique may be implemented, which includes determining derivatives, iterations, etc. For example, a solution may be found by iterating according to the Newton-Raphson scheme where such iterations may be referred to as non-linear iterations, Newton iterations or outer iterations. Where one or more error criteria are fulfilled, the solution procedure has converged, and a converged solution has been found. Thus, within a Newton iteration, a linear problem is solved by performing a number of linear iterations, which may be referred to as inner iterations.

As an example, a solution scheme may be represented by the following pseudo-algorithm:

// Pseudo-algorithm for Newton-Raphson for systems
initialize(v);
do {

//Non-linear iterations
formulate_non_linear_system(v);
make_total_differential(v);
do {

// Linear iterations:
update_linear_system_variables(v);

}
while((linear_system_has_not_converged(v));
update_non_linear_system_after_linear_convergence(v);

}
while((non_linear_system_has_not_converged(v))

As an example, a solver may perform a number of inner iterations (e.g., linear) and a number of outer iterations (e.g., non-linear). As an example, a number of inner iterations may be of the order of about 10 to about 20 within an outer iteration while a number of outer iterations may be about ten or less for an individual time increment.

As an example, a method can include adjusting values before performing an iteration, which may be associated with a time increment. As an example, a method can include a reception block for receiving values, an adjustment block for optimizing a quadratic function subject to linear constraints for adjusting at least a portion of the values to provide adjusted values and a simulation block to perform a simulation using at least the portion of the adjusted values.

As mentioned, fluid saturation values can indicate how fluids may be distributed spatially in a grid model of a reservoir. For example, a simulation may be run that computes values for fluid saturation parameters (e.g., at least some of which are “unknown” parameters) as well as values for one or more other parameters (e.g., pressure, etc.).

As mentioned, a simulator may implement one or more types of adjustment techniques such as, for example, one or more of time step adjustment and grid adjustment, which may be performed dynamically. As an example, a simulator such as a reservoir simulator may implement one or more of such adjustment techniques.

As mentioned, a simulation may account for one or more thermal processes where, for example, there can be displacement of a thermal front (e.g., a combustion front, a steam chamber interface, etc.), around which most fluid flows takes place. As an example, a dynamic gridding approach may aim to keep a finer scale representation of a grid around the thermal front and a coarser scale representation of the grid at some distance from the front. Through use of the coarser scale representation of the grid, the number of equations/number of variables may be reduced, which can reduce matrix sizes, etc., of a simulator and thereby allow the simulator to operate more effectively.

As an example, a simulator can commence a simulation with an original or initial grid. As the simulator operates to generate simulation results, the simulator may re-amalgamate its grid cells, while keeping some regions (for example around wells) finely gridded. The simulator may identify a moving front through one or more large spatial gradients of one or more specific properties (e.g., temperatures, fluid saturations and compositions, etc.). In the front vicinity, the simulator may de-amalgamate the originally amalgamated cells, and later on re-amalgamate them once the front has passed through a spatial region (e.g., a region of a subterranean formation such as a reservoir formation). As an example, amalgamated cells may be assigned up-scaled properties, for example, upscaling being based upon one or more types of averaging techniques.

As to thermal simulation, a simulator may include one or more features of a simulator such as the STARS simulator (Computer Modelling Group Ltd (CMG)). As an example, simulations may involve combustion and/or SAGD simulations. As an example, a simulator may operate according to a metric such as CPU time. As an example, a quantitative measure of efficiency can be CPU time in relationship to accuracy.

As explained, reservoir flow simulation benefits from representing an underground environment accurately, particularly where one or more fronts may exist, which may vary spatially and change differently in space with respect to time. For example, a front may be a relatively planar front at a particular spatial scale in a region or, for example, a front may include fingers, curves, etc. As an example, a front's shape may change with respect to time, in terms of overall extent and geometrical shape (e.g., planar, curved, fingering, etc.). Such variations can pose challenges in dynamic gridding.

As mentioned, thermal processes can involve convective, diffusive and dispersive flows of fluids and energy, which may lead to the formation of fluid banks and fronts moving in the reservoir. Some of these fronts may represent interfaces between mobilized oil, which is hot and has had its viscosity reduced, and the more viscous oils which are as yet unaffected by heat energy. As an example, other fronts can occur between phases, such as where a leading edge of hot combustion gas moves into an uncontacted oil. Such interfaces may be thin when compared to a cell size of a grid (e.g., an original grid) used to model EOR processes in a simulator. As such, challenges exist in how to properly represent various types of fluid physics near interfaces. As mentioned, use of fine scale computational grid cells throughout a reservoir can be prohibitively expensive as to computational demands. To address various issues, an integrated approach may be taken where, for example, various frameworks can be operated in a coordinated manner.

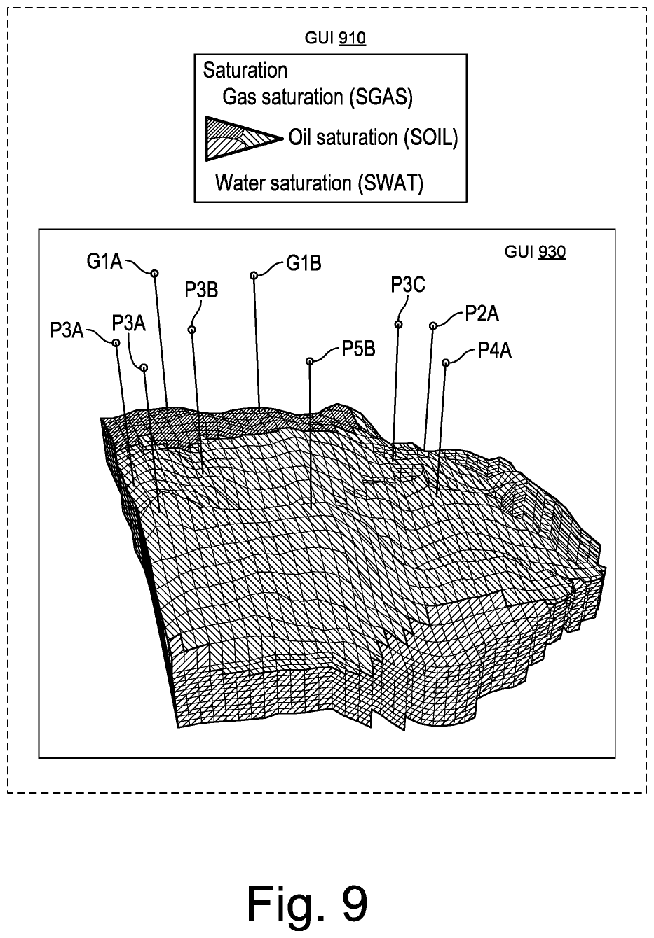

FIG. 9 shows examples of graphical user interfaces 910 and 930, which show values as to saturation for gas, oil and water in a model of a reservoir that includes a plurality of wells. As an example, output from a simulator such as described with respect to FIG. 8, may be utilized to generate one or more GUIs.

As an example, a system can be a living integrated asset model (LAM) system that can may be operatively coupled to one or more computational frameworks (e.g., TECHLOG framework, AVOCET framework, modeling frameworks, etc.). A LAM system can be for infrastructure utilized in one or more field operations that can aim to produce hydrocarbon fluids from one or more fluid reservoirs in the Earth.

A LAM system can improve asset modelling practices. For example, consider features of a LAM system can provide for keeping asset models (e.g., pore to process) up-to-date that can be used as “Truth model” for confident decision making at various stages of field lifecycle. Such an approach can deliver a new improved structured framework to keep models live with reservoir and operational changes by increasing efficiency and reducing the decision cycle time. As an example, a LAM system may be applied to an integrated asset modelling project for asset optimization to maximize hydrocarbon production.

A LAM framework and associated workflow can provide solutions to maximize the hydrocarbon production of a digitally enabled field, for example, by maintaining an underlying system that keeps models live/up-to-date with the current conditions of reservoir and production for the optimizing the asset (e.g., reserves of hydrocarbons, etc.). An underlying system can acquire simulation data from current production to validate an integrated asset model, which couples single or multiple reservoirs, wells, networks, facilities and economic models. As an example, a LAM system can utilize and/or interact with various frameworks such as IAM and other reservoir (INTERSECT, ECLIPSE, etc.), network (PIPESIM, etc.), facilities (VMG, ICON, etc.), economics (PEEP, etc.), and operation (AVOCET, AWM, etc.).

As an example, a LAM system can keep models live/up-to-date with current reservoir and production changes. For example, in a digital oilfield, one can create an accurate Field Development Plan for a brown field, while also aiming to efficiently maintain a plateau while maximizing recovery. For mature fields there is often old technology and manual data processing and a full understanding of the asset tends to be unavailable and analyzing it can be very slow (e.g., execution of simulator(s), etc.) and results that may be inaccurate without a reliable manner to verify (e.g., validate). As an example, a LAM system can help with multiple locations, teams and domains that perform modelling such that reservoir-production-facility interactions are considered and verifiable for accurate short, medium and long term decision making. A LAM system may reduce delays in model updates, which can shorten the time for engineering analysis with resulting efficiencies.

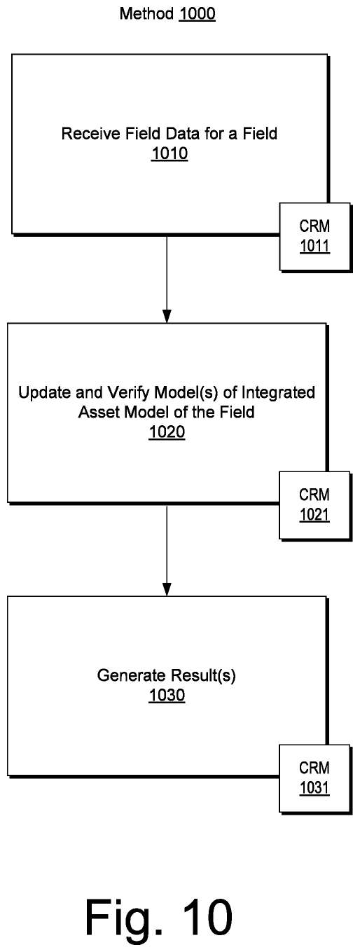

FIG. 10 shows an example of a method 1000 that includes a reception block 1010 for receiving field data (e.g., and optionally other data) for a field, an update and verify block 1020 for updating and verifying one or more models of an integrated asset model of the field and a generation block 1030 for generating a result or results using the integrated asset model. In such an example, the integrated asset model can be evergreen in that it is updated and verified via updating and verifying models of the integrated asset model.

The method 1000 is shown in FIG. 10 in association with various computer-readable media (CRM) blocks 1011, 1021, and 1031. Such blocks generally include instructions suitable for execution by one or more processors (or processor cores) to instruct a computing device or system to perform one or more actions. While various blocks are shown, a single medium may be configured with instructions to allow for, at least in part, performance of various actions of the method 1000. As an example, a computer-readable medium (CRM) may be a computer-readable storage medium that is non-transitory and that is not a carrier wave. As an example, one or more of the block 1011, 1021, and 1031 may be in the form processor-executable instructions, for example, consider the one or more sets of instructions 270 of the system 250 of FIG. 2.

As an example, the method 1000 can be utilized for decision making and action in a field. Such action may be control action, action to add equipment, remove equipment, etc. As an example, consider controlling a choke of a well or wells to arrive at a desired flow rate of fluid at one or more surface facilities. As an example, consider implementation of a LAM system for gas flow optimization. In such an example, data may be received and/or a simulation may indicate that a gas injection rate is too high and that it is desirable to reduce the gas injection rate. Such a scenario may result in a flag being issued, an alarm being issued, generation of alternatives, etc. For example, consider an approach that updates and verifies a surface network model (e.g., PIPESIM, etc.) based on an issue with gas and that then executes an IAM that includes the verified surface network model to determine an optimum gas injection rate (e.g., gas flow rate at one or more points). In such an example, a current rate may be 1.1 whereas the IAM indicates that 0.5 is optimum. In response to determination of the optimum value, a controller may issue a control signal that is routed to a gas lift valve or gas lift valves to adjust one or more components of the gas lift valve or valves to adjust the rate to the optimum. As an example, such a workflow may be a closed-loop workflow that is automated where a model of an IAM is updated “live” and a field controlled “live”. As an example, a control decision may be contingent, for example, upon one or more conditions precedent (e.g., green lights for other gas operations, receipt of input via an operator, etc.).

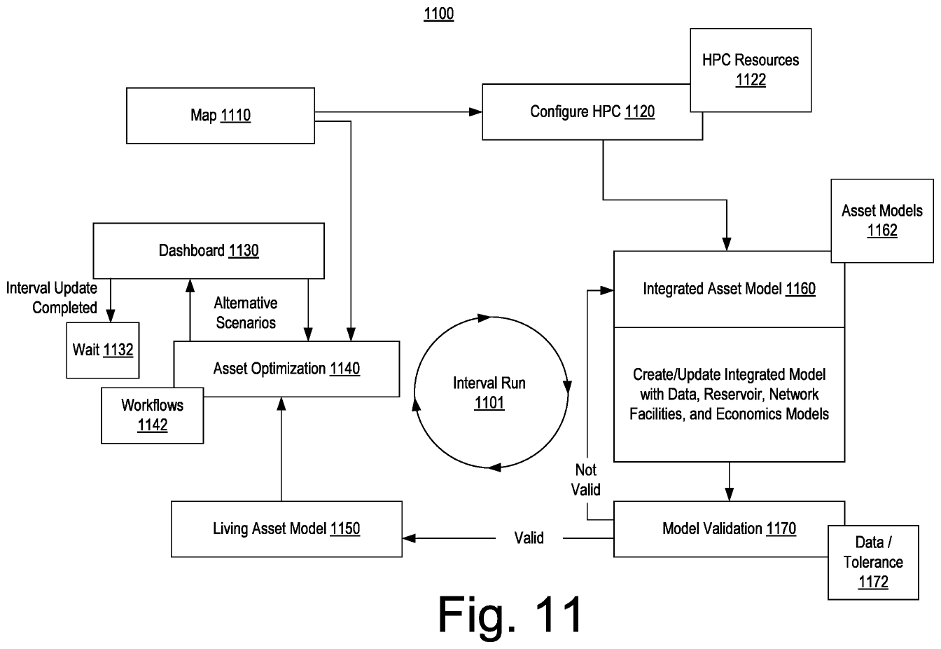

FIG. 11 shows an example of a LAM process or workflow 1100, which can include multiple workflows. As shown, a block indicates that a living asset model acts to assure that models are up-to-date for a field.

As shown, the process 1100 can be executed in a manner that involves an interval run 1101, which can be repeated for a desired interval period (e.g., daily, weekly, monthly, quarterly, etc.). Various operations in the process 1100 can be on-going and various operations can be periodic, for example, as governed by an interval period, etc.

As an example, the process 1100 can commence in a mapping block 1110 that can map existing ways of working, existing operations, etc., to one or more workflows. As shown, the mapping to a workflow or workflows via the mapping block 1110 can instruct a configuration block 1120 for configuring high-performance computing (HPC) resources 1122, which can include provisioning, etc., for example, of resources that may be in a server farm, the cloud, etc.

In the example of FIG. 11, the mapping block 1110 can also instruct an asset optimization block 1140, which can create multiple planning and/or operational workflows. The asset optimization block 1140 can be interactive with a dashboard component 1130, which can be utilized for rendering various graphical user interfaces (GUIs), for example, to generate one or more scenarios, which can include one or more alternative scenarios that can be fed to the asset optimization block 1140 for creating one or more workflows 1142. For example, a created workflow may not cover a particular scenario that is of interest to an operator of a LAM system such that the dashboard component 1130 can be utilized to interactively create a workflow (e.g., modify, etc.) to address that particular scenario. As indicated, the dashboard component 1130 can output a completion signal, for example, to indicate that, for an interval, the process 1100 has been completed. In such an example, the process 1100 may enter a wait block 1132, which can provide for waiting until it is time to complete a subsequent interval (e.g., daily, weekly, monthly, quarterly, etc.). During a wait period, the dashboard component 1130 may be utilized to view various types of data, workflows, etc., which may pertain to executing components that are in the process of completing a subsequent interval. As explained, the process 1100 can include various on-going operations and various timed operations, where a timed operation may pertain to an interval (e.g., outputting an indication that an integrated asset model (IAM) is valid for use during a particular interval, etc.).

As shown, in the example of FIG. 11, the asset optimization block 1140 receives a valid living asset model (e.g., a valid living integrated asset model) from a living asset model block 1150. As to validation, consider utilization of provisioned HPC resources of the HPC resources 1122 by an integrated asset model block 1160 that is operatively coupled to various asset models 1162 where the integrated asset model block 11660 can provide for creation, update, etc., of an integrated model with data, reservoir, network facilities, and economic models. As shown, the integrated asset model block 1160 can output an integrated asset model to a model validation block 1170, which can be operatively coupled to one or more resources for data access and/or tolerance computations 1172, for example, tolerance with respect to measured data. The model validation block 1170 can, based on data and/or tolerance(s), decide whether an integrated asset model is valid or not sufficiently valid. For example, where a tolerance is greater than a limit, the integrated asset model may be deemed to be not valid, which can cause the integrated asset model block 1160 to “try again”, for example, by reassessing one or more of the various individual asset models 1162. For example, one of the individual asset models 1162 may have been in a state of revision, update, data disconnect, etc., which may have caused a lack of tolerance and hence the decision of “not valid”.

As explained, a validation process may be an on-going loop that aims to make an integrated asset model a living integrated asset model (LAM). Where the validation process is on-going, it may incrementally refine a LAM such that at an interval, the LAM can be a result of incremental improvements that account for the latest revisions, etc., to one or more of the asset models 1162. Such an approach can increase confidence in the signal issued by the dashboard component 1130 that the interval update being completed has output, in a timely manner, a valid LAM, which may be suitable for one or more uses.

As an example, a LAM, a LAM system and associated workflows can offer solutions to maximize hydrocarbon production through interactions with field equipment where the LAM system acts to keep one or more models live/up-to-date with the current conditions of reservoir and production for the optimizing the asset. For example, a LAM system can provide for acquiring simulation data from current production to validate an integrated asset model, which couples single or multiple reservoirs, wells, networks, facilities and economic models. As an example, a LAM can enable a digital oilfield's end-to-end surveillance for a fuller understanding of a so-called hydrocarbon pathway to facilitate the successful optimization of the asset.

As an example, a LAM framework can provide a single framework that combines reservoir with network, process, and economic models, which facilitates decision making by including subsurface and surface constraints to accurately model capturing the pore to process interactions of the asset. Such a framework can establish an integrated framework by combining hardware corresponding with the size of models. A LAM framework can be a single framework to handle schedule of operations and dependencies between different parts of oilfield by a high-level asset-based strategy. As an example, a LAM framework can enable collaboration to increase efficiency of decision making. As an example, multiple disciplines can rapidly address (e.g., rectify) inaccuracies between the boundary conditions of reservoir, network, and facilities to focus on planning or operational challenges to unlock oil and maximize production NPV. As an example, a LAM system can include algorithms and criteria of update of models. As an example, a LAM system can include a single continuously updated framework, which can provide a foundation to build multiple workflows for fast, medium, and slow loop workflows (e.g., workflow loops of different frequency, time scales, etc.).

As shown in FIG. 11, a LAM process may be defined using phases. For example, consider a business workflow as to an asset. The first phase of a LAM workflow can be to combine a manner of working in domain specific silos to come up with an integrated workflow, which can always be up-to-date (e.g., living). As an example, a LAM process can validate each type of model (e.g., reservoir model, network model, facilities model, and economics model) by running them individually. If each model runs successfully, then a LAM process can proceed; whereas, if not, then flag can be generated as invalid and send the model to rectify. From the different combinations of the base domain models, strategies from monthly update various Planning and Operational workflows can be created depending upon different phases of oilfield lifecycle. As an example, a Decision Dashboard can allow for collaboration for decision making for different planning and operation.

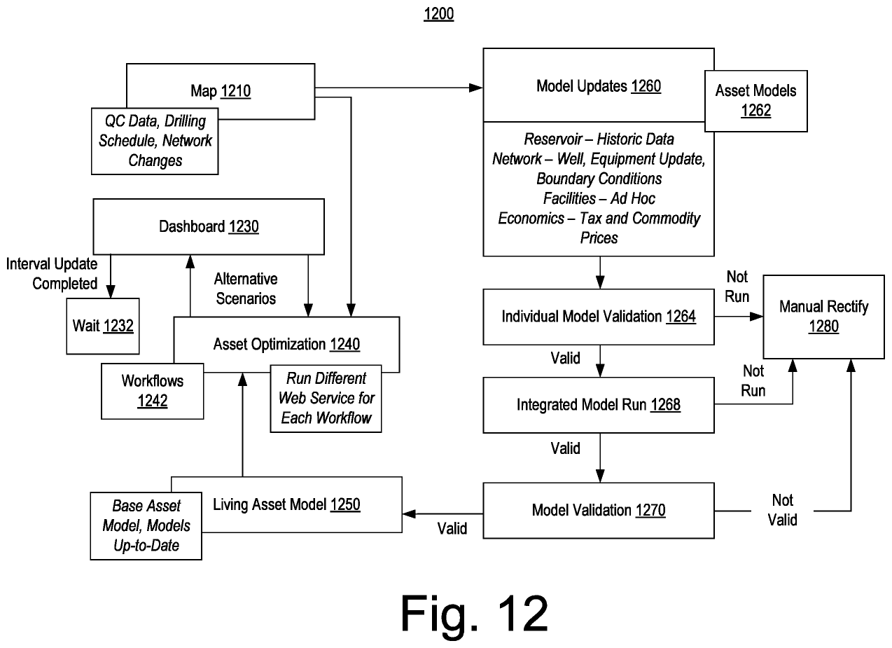

FIG. 12 shows an example of a workflow 1200. In the workflow 1200, there can be decisions as to validity where, for example, where validity is not confirmed, a process may rectify, optionally through manual rectification. Such an approach can be collaborative in that a dashboard may indicate when a model has not been validated and provide a time frame in which validation may occur (e.g., Jane is working on revision, estimated to be complete at 13:15). In such an approach, a time estimate can be provided for when a live model has been validated (e.g., verified). For example, consider the graphics in the workflow 1200, which may be rendered as GUIs to one or more displays.

As shown in the example of FIG. 12, a LAM system such as that illustrated via the process 1100 of FIG. 11 can be tailored and instructed to operate in a particular manner. In the example of FIG. 12, the workflow 1200 is illustrated without some blocks as in FIG. 11 and with some additional detailed blocks. For example, while HPC resources are not shown in FIG. 12, such resources can be provisioned and utilized. In FIG. 12, the blocks 1210, 1230, 1232, 1240, 1242, 1250, 1260, 1262 and 1270 correspond approximately to those of FIG. 11, particularly the blocks 1110, 1130, 1132, 1140, 1142, 1150, 1160, 1162 and 1170. The example of FIG. 12 shows additional blocks 1264, 1268 and 1280 as being part of a validation process. For example, the block 1264 provides for individual model validation such as by individual model execution runs, which if not successful, direct the workflow 1200 to the block 1280 as a manual rectification block where a user may interactively utilize a GUI, etc., to rectify an individual model such that a successful execution of that individual model can be achieved. In such an approach, the block 1264 may issue a signal, for example, via the block 1230, etc., to indicate that an individual model is not executing in a manner that is sufficient for validation thereof. Similarly, the block 1280 can be utilized where the block 1268 decides that an integrated asset model cannot be executed in a manner that is sufficient for validation thereof. As shown, where valid executions can be achieved in the blocks 1264 (e.g., for each of the individual asset models 1262) and 1268 (e.g., for an IAM), then the process 1200 can proceed to the model validation block 1270, which, as explained with respect to FIG. 11, can utilize data, tolerances, etc., to decide whether the IAM is valid.

In FIG. 12, the workflow 1200 (e.g., or process) includes mapping in the mapping block 1210 where, for example, the mapping can include quality control data, drilling schedule concerns, network changes, etc., which may be directed to the asset optimization block 1240 where different web-based services may be run for each workflow that has been mapped. As explained, such workflows can utilized the LAM of the block 1250, as deemed valid by the model validation block 1270. As indicated, the dashboard component 1230 can output various results, provide for scenario editing, new scenarios, etc., where such scenarios can utilize the validated IAM of the block 1250, for example, in workflow executions that utilize individual web-based services (e.g., a QC workflow, a drilling schedule workflow, a network change workflow, etc.).

As explained, the mapping block 1210 can receive various types of information from which workflows can be configured and executing where such workflows can be assured that a common living integrated asset model that has been validated is utilized. In such an approach, the results from the workflows can be compared and/or consolidated as being based on the common validated LAM.

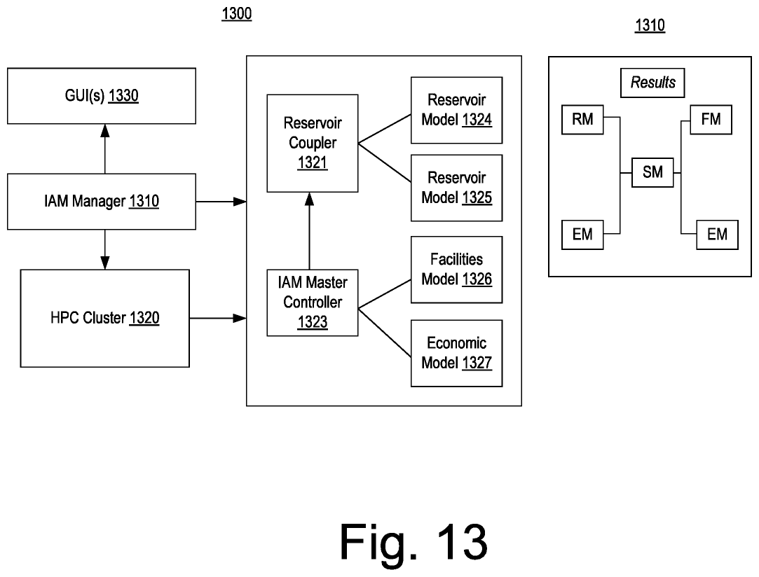

FIG. 13 shows an example of a high-performance computing (HPC) architecture 1300 and a GUI 1310 with some examples of models that can be part of an IAM manageable via a LAM system. For example, consider a reservoir model (RM), a surface network model (SM), an earth model (EM), a facilities model (FM), and an economics model (EM). Each of the models may be associated with a particular, specialized framework (e.g., ECLIPSE, PETREL, PIPESIM, PEEP, etc.), which may be selected via a menu, for example, from a group of reservoir model frameworks, a group of production model frameworks, from a group of process model frameworks, from a group of fluid model frameworks, from a group of economics model frameworks, etc. As an example, the GUI 1310 can be utilized to define an IAM, for purposes of a process such as the process 1100 of FIG. 11.

As shown, the architecture 1300 can include an IAM manager 1310 that interacts with a HPC cluster 1320 where one or more GUIs 1330 can provide for interactions, visualizations, etc. As shown, the architecture 1300 can include a reservoir coupler 1321 that can couple multiple reservoir models 1324 and 1325 (e.g., for a region, etc.), and an IAM master controller 1323 that can operatively couple one or more models 1326 and 1327 with the reservoir coupler 1321.

As an example, a HPC cluster can be operatively coupled to an IAM manager, which may be configured for visualization tasks. The IAM manager and the HPC cluster can be operatively coupled to the LAM (e.g., integrated living asset model or living integrated asset model). As shown, computations may be performed in parallel or using discrete resources provisioned for particular models. As shown, a reservoir coupler can act to couple a reservoir model and a network model, for example, to assure that valid models are utilized as to modeling of fluid that may flow from a surface network to a reservoir (e.g., injection, etc.) or from a reservoir to a surface network (e.g., production, etc.).

As an example, a IAM framework can include one or more features of the IAM framework (Schlumberger Limited, Houston, Tex.), which is an open framework that enables the coupling of a wide number of simulation software applications including, for example, Reservoir simulation models (e.g., ECLIPSE industry-reference simulator for black-oil, compositional, thermal, and streamline reservoir simulation; INTERSECT high-resolution reservoir simulator that goes beyond the capabilities offered by conventional simulators; MBX material balance tank model for fast and simple reservoir modeling; IMEX reservoir simulator tool from Computer Modeling Group; MBAL material balance simulator from Petroleum Experts, etc.); Multiphase flow simulation models (e.g., PIPESIM steady-state multiphase flow simulator; OLGA dynamic multiphase flow simulator; GAP multiphase oil and gas software from Petroleum Experts, etc.); Process and facilities simulation models (e.g., HYSYS; Petro-Sim; UniSim process modeling tool; etc.); and Economics domain models (e.g., Merak Peep for full economics, portfolio, and reserves management). As an example, a system can include an OPC DA model adapter for real-time connection for digital oil field workflows.

As an example, in a phased approach of a LAM workflow, provisioning or other hardware/software set can be performed, for example, to match the complexity of the models involved. For example, a reservoir model can be low resolution or high resolution (e.g., spatially and/or temporally) depending upon the type of workflow. As an example, an IAM manager can coordinate different parts of a HPC server for IAM run control master controller, which runs a reservoir coupler as well as, for example, facilities and economics models. As an example, a reservoir coupler can demand relatively larger servers (as to computational resources) depending upon resolution and details of associated reservoir and network models. As an example, individual models can be run independently on different configuring nodes of a server to optimizer the number of CPUs and nodes required. As explained, computational resources may be tailored by a LAM system to meet demands imposed, which may vary over time (e.g., during a lifecycle of a field).

As an example, a LAM workflow can include setting up an Integrated Asset Model by conditioning individual domain models, and then combining them one by one to create and successfully run the IAM. In such an example, multiple planning and operational workflows can be created by combining different models, defining high-level strategies, addressing uncertainties, etc. Conditioning of each model can involve, first running them successfully, and then defining coupling constraints, locations or boundary exchange parameters with the model earlier.

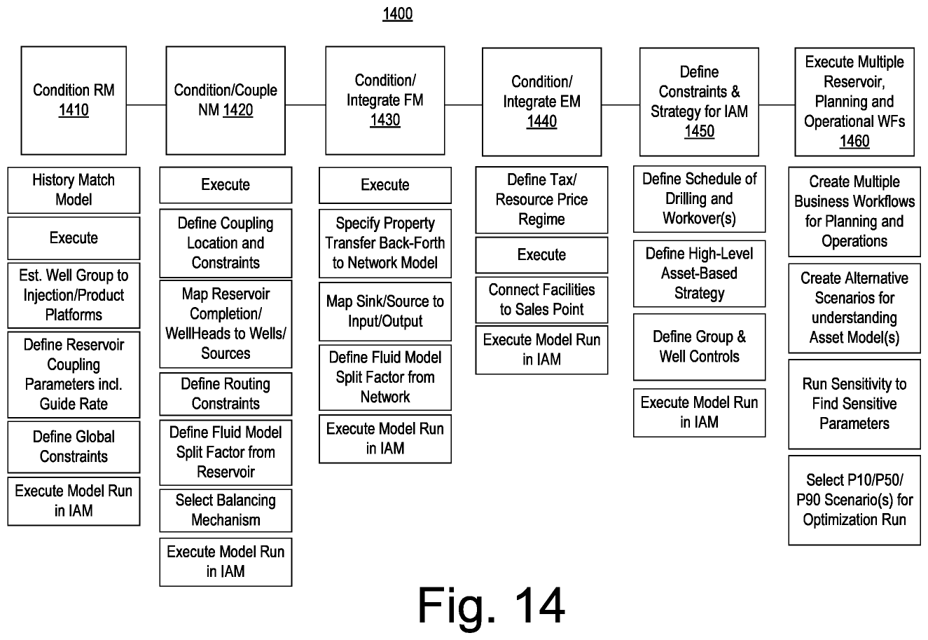

FIG. 14 shows an example of a GUI 1400 for an IAM. As shown, various processes can be implemented for building an IAM, which may be subjected to live updating per a LAM system.

In the example of FIG. 14, various processes include a condition reservoir model process 1410, a condition and couple network model process 1420, a condition and integrate facilities model process 1430, a condition and integrate economics model process 1440, a define constraints and strategy process for IAM 1450 and an execute multiple reservoir, planning and operational workflows (WFs) process 1460. As shown, each of the processes can be implemented in a series where various processes can include standalone execution and execution of a model run in an IAM.

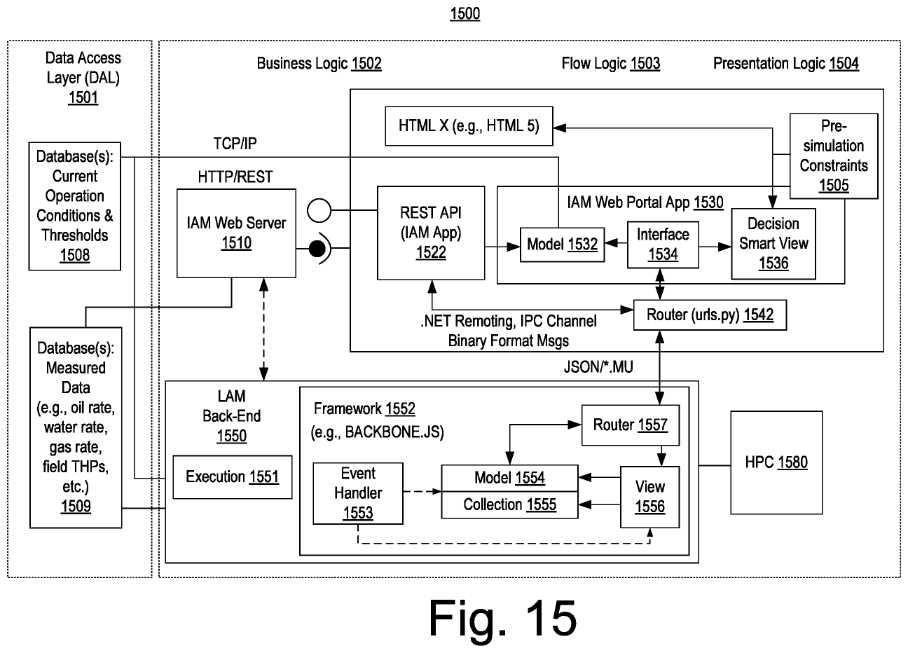

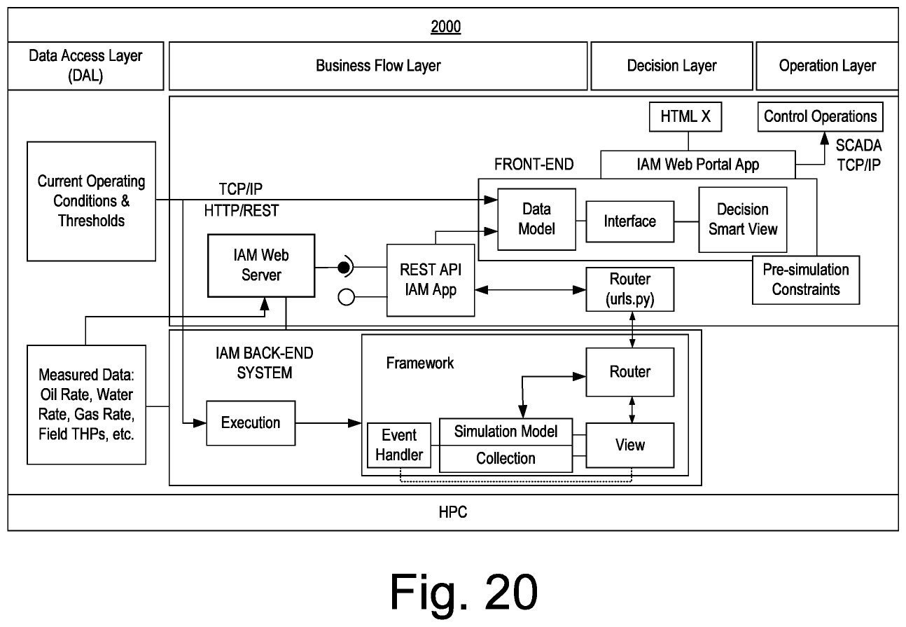

FIG. 15 shows an example of a LAM architecture 1500 (see also, e.g., FIG. 20). As an example, a LAM workflow can include instantiating a framework engine to support one or more workflows (see, e.g., workflow of FIG. 12, etc.).

The LAM architecture 1500 can include various front-end components and various back-end components and can provide for transmissions, communications, etc., using one or more types of protocols, routers, network equipment, etc. As shown, the LAM architecture 1500 can include one or more servers such as, for example, an IAM web server 1510 (e.g., a back-end component) that can be operatively coupled to one or more front-end components and one or more other back-end components.

As shown in the example of FIG. 15, an IAM web portal app 1530 can be part of a front-end system that allows for various user interactions, which can be, for example, via one or more types of application programming interfaces (APIs), .NET technologies, JavaScript technologies, PYTHON constructs, etc.

In the example of FIG. 15, the LAM architecture 1500 can include a front-end web portal as a web portal for the front-end (e.g., the IAM web portal app 1530) that can reside in a LAM back-end system 1550. Such a front-end web portal may be implemented using a framework 1552 such as, for example, the backbone.js framework. The back-end system 1550 can be operatively coupled to high performance computing (HPC) resources 1580 such that the framework 1552 can manage model updates, model validations, model integrations, model executions, etc. In the example of FIG. 15, the framework 1552 can provide for responding to user interactions via the IAM web portal app 1530 as well as coordinating various actions associated with a LAM, as provided at least in part using the HPC resources 1580.

As shown, the LAM back-end system 1550 can be operatively coupled to one or more databases for purposes of performing such actions. As shown, a database 1509 can provide various types of measured data as relevant to various models to be integrated into a LAM for purposes of model validations, including LAM validation.

As to scenarios, a user may, for example, utilize the IAM web portal app 1530 to input various types of information that can include pre-simulation constraints (see, e.g., a pre-simulation constraints block 1505), which may be selected automatically, customized, etc.

As to executions, an execution block 1551 is shown as being part of the LAM back-end system 1550 and it may operate automatically, for example, according to a set interval or set intervals, which may be adjustable. However, as a LAM may be utilized by various users, entities, controllers, etc., the execution block 1551 may be adjustable as to its interval or intervals by an authorized user that understands how a change or changes may impact other users, systems, etc., that may depend on a LAM being valid for a set interval. As mentioned, the pre-simulation constraints block 1505 may be utilized, for example, to provide for execution of desired scenarios, which may include customized executions. Such executions may utilize a LAM as validated per a set interval or set intervals.

As shown in the example of FIG. 15, the LAM architecture 1500 includes a data access layer 1501 with one or more databases 1508 and 1509 (e.g., historical, real-time, etc.), business logic 1502, flow logic 1503, and presentation logic 1504. The LAM back-end system 1550 can provide for various types of the business logic 1502, which, as explained, can include logic that validates and integrates models to provide a LAM for use by one or more users (e.g., via one or more instances of the IAM web portal app 1530). While the term “business logic” is utilized, as explained, the logic pertains to simulation models that are numerical models representing real-world entities of geologic environments, equipment, hydrocarbon containing fluids, etc. As explained, such logic can be utilize in controls where results generated via execution operations using the LAM back-end system 1550 can be a basis for control instructions that are transmitted to field equipment to perform one or more field actions.

In the example of FIG. 15, the pre-simulation constraints block 1505, as mentioned, can be utilized by the IAM web portal app 1530 and can inform the LAM back-end system 1550. As shown, the IAM web server 1510 can be operatively coupled to various components, for example, via a Representational State Transfer (REST) API/IAM App 1522, which can be operatively coupled to the IAM web portal app 1530, which is shown as including a model 1532, an interface 1534 and a decision smart view component 1536. In the example of FIG. 15, a router 1542 can provide for interactions with the IAM web portal app 1530 and the LAM back-end system 1550 that includes the framework 1552 as a sub-system. As shown, the framework 1552 as included in or operatively coupled to the LAM back-end system 1550 can utilize backbone.js as a type of framework.

The backbone.js framework can be utilized for one or more purposes. For example, it can give structure to web applications by providing models with key-value binding and custom events, collections with an API of enumerable functions, views with declarative event handling, and connections via an API over a RESTful JSON interface. The backbone.js approach can represent data as models, which can be created, validated, destroyed, and saved to a server. For example, whenever an action causes an attribute of a model to change, the model can trigger a “change” event; where various “views” of the model's state can be notified of the change, so that they are able to respond accordingly. A view can be used to reflect what a data model looks like. The backbone.js approach can include a router component that can be utilized for routing via URLs (see, e.g., the routers 1542 and 1557). As to a model in the backbone.js framework, it can include data, logic, etc., and be a representation of an entity such as, for example, a simulation model, which as mentioned, can be executable using the HPC resources 1580. In the backbone.js framework, a collection is a set of models where, for example, definitions can include types of models. The backbone.js framework can include one or more connections to one or more sources such as one or more servers that may be operatively coupled to one or more databases (see, e.g., the databases 1508 and 1509), one or more HPC resources (see, e.g., the HPC resources 1580), etc. A backbone.js framework may receive requests via one or more routers, which can route an application to events using URLs, may represent model state using views, and may utilize models and collection(s) to retrieve and populate data from one or more sources, for example, by binding events.

In the example of FIG. 15, a “view” component 1556 can be a back-end construct that is changed, for example, without rendering a view to a display (e.g., rendered views for a user can be handled via the IAM web portal app 1530 via the decision smart view block 1536, etc.). As explained, when a model changes, a view of the model's state can update.

As shown, the framework 1552 can include an event handler 1553 with appropriate connections to a model 1554 and collections 1555 sub-system and the view component 1556, which is operatively coupled to the router 1557 of the framework 1552 and where the router 1557 can operatively couple to the router 1542. As shown, the router 1542 may implement a dispatcher (e.g., urls.py), which may be written in the PYTHON language. The router 1542 can be a URL-based router where, for example, routing can include mapping URLs to code. For example, in PYTHON, there can be a set of URLs for the IAM web portal app 1530 where a URLconf (URL configuration) component can be PYTHON code for mapping between URL path expressions to functions (e.g., views, etc.). In such an example, a mapping can be as short or as long as appropriate and may reference one or more other mappings. In such an example, when set forth in PYTHON code, it may be constructed dynamically. As shown, the system 1550 may communicate (e.g., the router 1557 to the router 1542) using JSON (JavaScript Object Notation as a data-interchange format, etc.). The framework 1552 may utilize messaging and asynchronous calls (see, e.g., dashed lines; where solid lines can indicate invocations).

As shown in the example of FIG. 15, TCP/IP, HTTP/REST, etc., may be utilized for purposes of transmissions, communications, signaling, etc. A user may interact with a GUI such that front-end actions cause back-end actions.

In the example of FIG. 15, the IAM web server 1510 can be part of a scheduler sub-system that operates to assure, for each periodic time (e.g., monthly, etc.), the proper actions will be taken. For example, the execution block 1551 can be driven in part by data, one or more actions, etc., provided by the IAM web server 1510. The IAM web server 1510 can co-ordinate updates of data in one or more databases, updates of model management and updates, validation, communication with the IAM web portal app 1530, for example, via the REST API 1522 to run, visualize current data, etc., for example, via the decision smart view block 1536. The IAM web server 1510 may also provide for raising an alarm if validation is not successful.

As mentioned, the framework 1552 can be configured to handle updating each individual model according to various types of inputs, which can include one or more pre-simulation constraints (see, e.g., the block 1505). The framework 1552 can then provide for execution and validation of each model by communicating with various back-end resources. As an example, the framework 1552 can provide for raising an alarm if a standalone execution run is not successful or an integrated asset model execution run is not successful.

As to the IAM web portal app 1530, it can provide for executing an IAM via interaction(s) with the framework 1552 that can provide for use of updated domain models and applying an asset management strategy (AMS), for example, after a standalone run has been successfully executed. The IAM web portal app 1530 can communicate with the IAM web server 1510 via the REST API 1522. As an example, results can be stored in one or more databases as well as, for example, displayed in via the decision smart view block 1536.

As an example, one or more operational settings can be sent to field equipment (e.g., SCADA, etc.) for one or more changes to field equipment settings. Such an approach can be automatic and/or via user interaction with the IAM web portal app 1530. In such a manner, the LAM architecture 1500 can be utilized to implement a control process that acts to control field equipment that can perform one or more field operations using knowledge from execution of an IAM, which as mentioned can be referred to as a living integrated asset model (LAM).

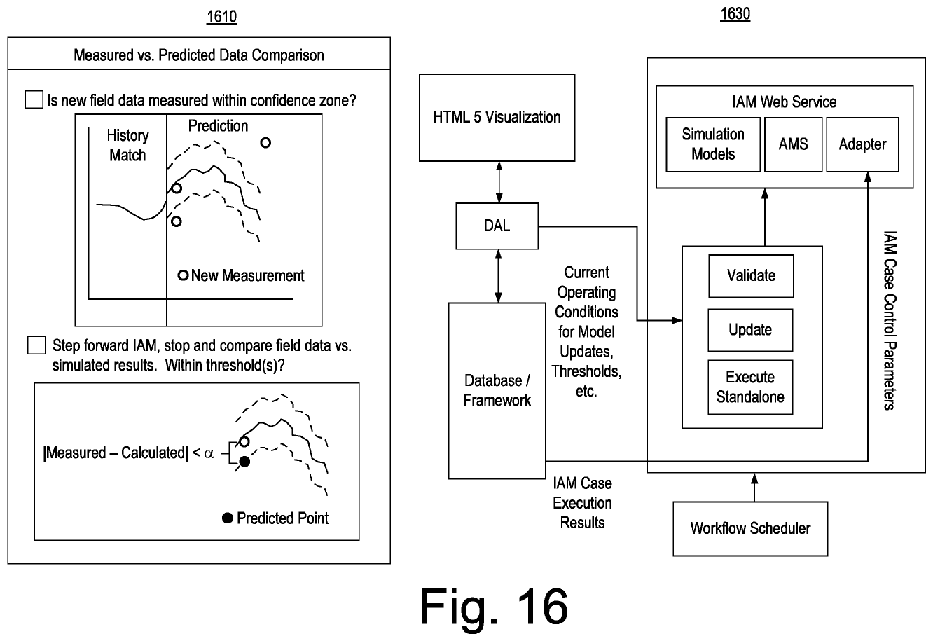

FIG. 16 shows an example of a GUI 1610 that can be utilized for model validation (e.g., quality control, verification, issuance of flags, alarms, etc.) and an example of a LAM system 1630. As explained, model validation can be performed on a well by well basis by checking if a difference between simulated results (prediction) and field production operational data (measured) is within a predefined threshold. If so, then the IAM can be deemed calibrated and suitable for the prediction. As an example, a threshold can be defined to compare measured field data against simulated results. Such a threshold can be lower or equal to an absolute value of a difference between measured data value minus calculated value. For example, consider:

|MEASURED−CALCULATED|/MEASURED≤α

where α can be a user defined threshold (operational tolerance) per well or field. Such a factor may be based on availability of data, data quality and associated uncertainty in the reservoir modelling.

As shown in FIG. 16, the GUI 1610 can include controls to determine if new field data that has been acquired is within a confidence zone. Such a GUI can include a history match window and a prediction window where new measurements can be plotted. As an example, a GUI can allow for stepping forward (e.g., proceeding with a workflow) in a manner that compares field data to simulation results, for example, to determine whether something is within a threshold.

As an example, a workflow can include asset optimization and rendering a decision dashboard for visualization. For example, consider operating a LAM system to use a base model as generated and running reservoir, planning and operational workflows to improve CAPEX/OPEX cost.

As shown in FIG. 16, the LAM system 1630 can include features for model updates, model validation (e.g., verification), and execution of a model of an integrated asset model (IAM) on a standalone basis, which may be part of a model validation process. For example, the LAM system 1630 can be configured to perform one or more of the operations as explained with respect to the GUI 1610. For example, a validation can be performed using measured versus predicted information. In such an approach, measurements can be rendered with respect to one or more threshold(s). In response, the LAM system 1630 can either proceed to a verification or proceed to revision (e.g., optionally waiting or issuing a flag for a domain expert or experts).

As shown in the example of FIG. 16, the LAM system 1630 can include features that operatively couple to a framework such as the AVOCET framework (Schlumberger Limited, Houston, Tex.). The AVOCET framework can collect, store, and display various types of production operations information—surface, wellbore, wellhead, and facilities data—with measurements—well test data, fluid analyses, transfer tickets, and tank inventories—to enable users to view and track forecasts, production targets, budgets, and other performance indexes, for example, at one or more of a corporate, business unit, or geographical level. With cross-domain workflows and integration, users can visualize and interact with assets using a system such as the LAM system 1630.

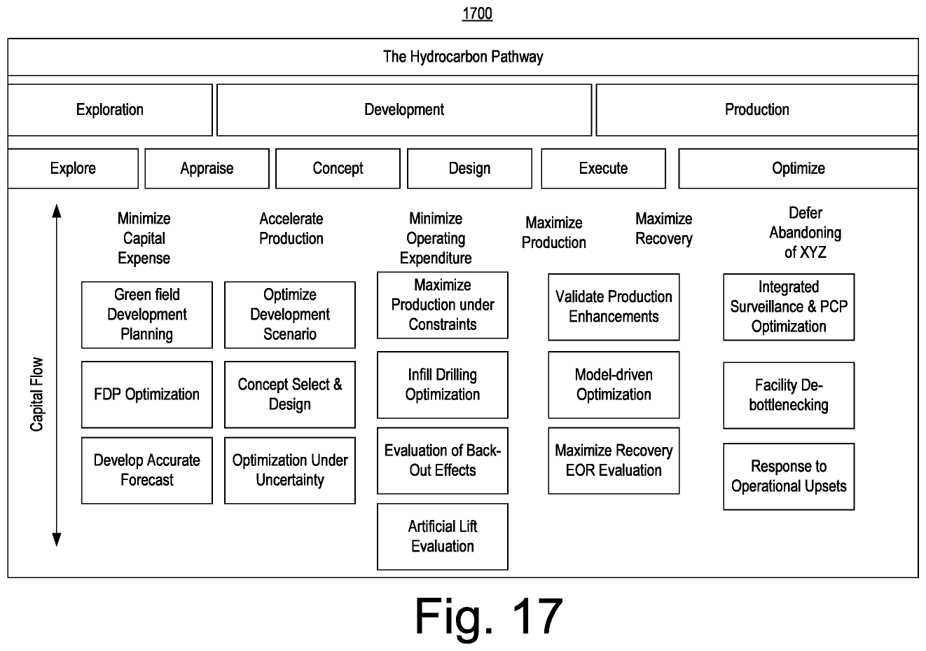

FIG. 17 shows an example of a GUI 1700 that includes various graphics associated with a hydrocarbon pathway, which can include exploration, development, and production phases. As an example, the GUI 1700 may be utilized with respect to short term operations (e.g., surveillance, equipment health monitoring, visualization, allocation); flow assurance (e.g., debottleneck pipeline network field processing facilities, understanding effects of transient well and reservoir behavior on production efficiency via use of “what if” scenarios, understanding transient behavior of complex networks by combining a steady state to a transient flow simulator); and long term planning (e.g., achieve more accurate forecasts by accounting for the interactions of subsurface deliverability with surface backpressure constraints, model compositional blending, mixing, injection of multiple producing zones and reservoirs to meet product specifications, automatically optimize artificial lift, EOR and IOR injection utilization with live asset model updated on real-time or on-demand, etc.). As an example, for each workflow, an IAM system can generate an associated dashboard.

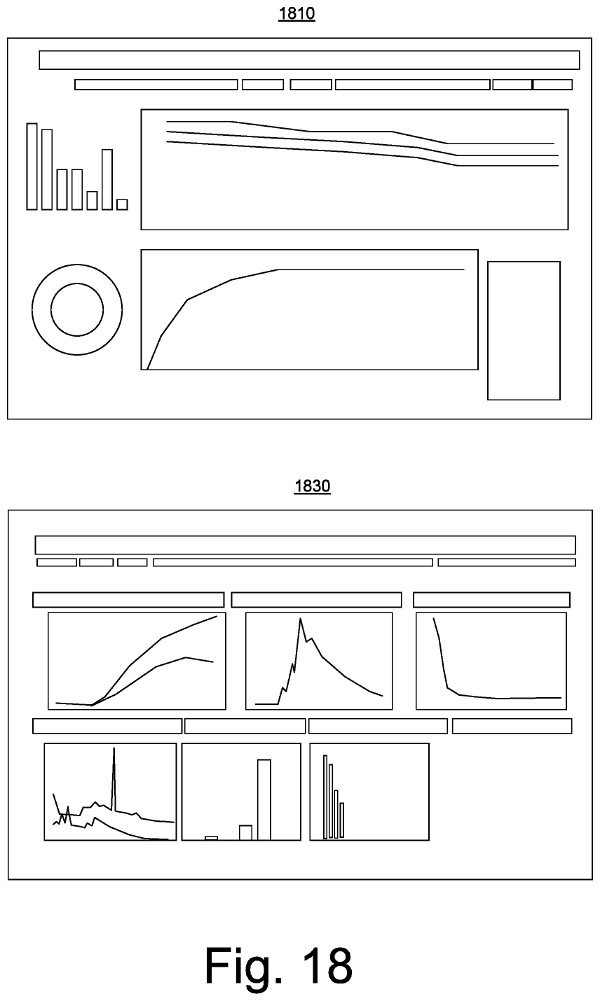

FIG. 18 shows examples of GUIs 1810 and 1830 as dashboards for particular workflows. Such GUIs may show results, which can include analytics. As an example, a GUI may provide for visualization on a well by well basis, a group of wells basis, a full field basis, which may be at an asset level. As an example, a GUI can include input parameters and thereby be interactive for controlling one or more workflows and/or for assessing strategies for running one or more alternative scenarios. Such an approach can enable collaboration to increase efficiency of decision making. As an example, individuals from multiple disciplines can be notified to be quickly involved in addressing one or more inaccuracies such as, for example, in accuracies between the boundary conditions of reservoir, network, and facilities. An LAM system can allow for a focus on planning or operational challenges to unlock oil and maximize production NPV. Interdependency between workflows and a framework can act to keep an IAM evergreen with current changes in a field and/or elsewhere. Such an approach can be efficient for decision making to optimize an asset.

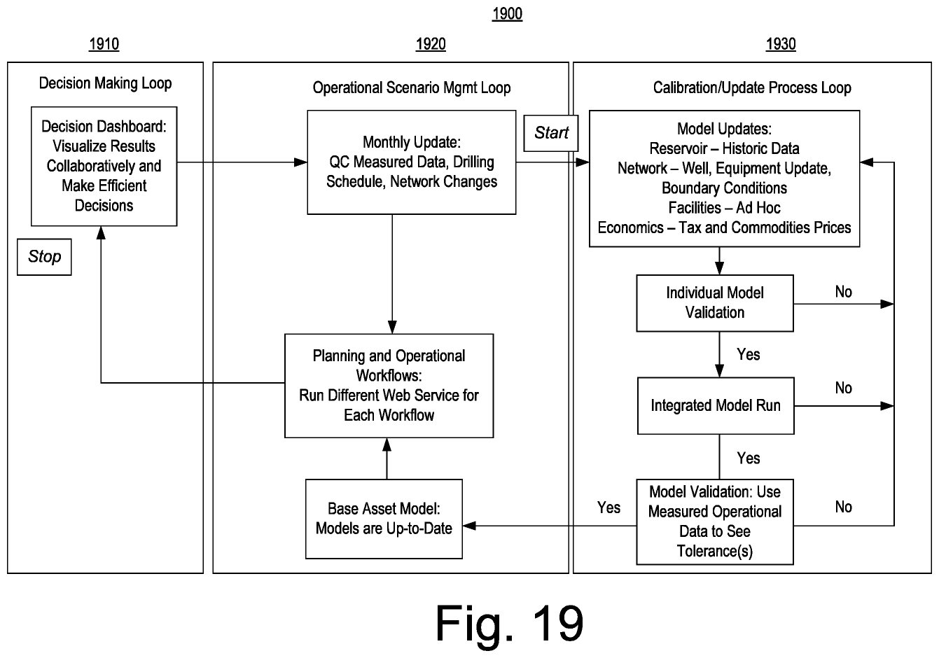

FIG. 19 shows examples of workflows 1900 as associated with various types of equipment, geologic environments, etc. The workflows can be implemented using various components that can be part of a computational framework. As shown, components can include a decision making loop component 1910, an operational scenario management loop component 1920 and a model calibration and update process loop component 1930.

The component 1910 can include a GUI such as a dashboard GUI that can provide for rendering graphics for visualizing results, collaboratively making efficient decisions, etc. As shown, the component 1910 can receive and output information to the component 1920, for example, output to improve operations of the component 1920 and input as to planning and operational workflows.

The component 1920 can include various features, including an update feature for quality control measured data, drilling schedules, network changes, etc.; a planning and operational workflows feature for running different web services for particular workflows and an asset model feature for models that can be updated models, for example, per a validation feature of the component 1930.

The component 1930 can include a model update feature for updating models such as a reservoir model (e.g., using historic data, etc.), a fluid network model (e.g., as to wells, equipment updates, boundary conditions, etc.), a facilities model, and an economics model (e.g., via tax, commodity pricing, etc.). As an example, resources expended to operate equipment, produce fluid, separate fluid, process fluid, etc., may be balanced against availability and costs of such resources. Such an approach can consider financial costs, logistics, risks to equipment, risks to people, long-term production considerations, etc.

The component 1930 is shown as including an individual model validation feature that can determine whether an individual model is valid (see, not valid and valid arrows), where a model is deemed valid, the component 1930 can progress to an integrated model run feature that can execute an integrated model, for example, to determine whether execution is successful (e.g., results generated, acceptable results generated, etc.). As shown, decisions can include valid and not valid where a valid decision leads to a model validation feature that can utilize measured operational data to see tolerances (see, e.g., the GUI 1610 of FIG. 16).

As shown in the component 1930, a not valid loop can continue to the model update feature. Such an approach can be performed iteratively for a plurality of models to generate (e.g., manage and/or maintain) a live integrated asset model (LAM) for field operations. As mentioned, such a LAM can include a reservoir model and a network model that can be operatively coupled for purposes of producing and processing reservoir fluids. Where such producing and processing occurs, a LAM can be updated in real-time, for example, according to set timing intervals, which can have physical meaning, physical constraints and/or computationally linked constraints (e.g., time to execute a simulator to reach a converged solution as to physical phenomena, etc.).

As an example, a LAM system can combine ways of working in domain specific silos to generate an integrated workflow (or workflows), which can be up-to-date and hence “living”. For example, consider a method that includes:
1. Receive monthly updates of measured data, drilling schedule and network topology or equipment changes. The data can be quality controlled (QC) (e.g., outliers addressed, cleansed, statistically processed, etc.).
2. Depending upon the data obtained in 1, the method can update each domain model, which can include models such as:
   a. Reservoir model (historic data and wells)
   b. Network model (well, equipment update, routing, boundary conditions etc.)
   c. Facilities model (ad hoc, new compressors, boundary conditions etc.)
   d. Economics model (tax and commodity prices, resource logistics)
3. Validate each reservoir model, network model, facilities model, and economics model by running them individually. If each model runs successfully, then proceed; if not, then flag it as invalid and send the model to rectify (e.g., automatically and/or manually). As an example, a model can be flagged for assessment by an appropriate domain engineer to fix the model accordingly. After modifying the model, a check can be made to assure that the model contains appropriate updated values, hence return to 2.
4. Run integrated model successfully and run the model validation on a well by well basis by checking if the difference between simulated results (prediction) and field production operational data (measured) is within a predefined threshold (or thresholds). If so, then the LAM is deemed calibrated and suitable for the prediction. A threshold can be defined in order to compare measured field data against the simulated results. This threshold is lower or equal to the absolute value of the difference between the measured data value minus the calculated value as it is shown below:

|MEASURED−CALCULATED|/MEASURED≤α

where α may be a user defined threshold (operational tolerance) per well or field. It may also be advisable to carefully define this factor based on availability of data, data quality and associated uncertainty in the reservoir modelling. If a model is valid go to next step, else return to 2.

As explained with respect to FIG. 19, a LAM system can provide the following:
1. From different combinations of base domain models, strategies from periodic (e.g., monthly or other) updates can be utilized for various planning and operational workflows, which may be created depending upon different phases of oilfield lifecycle.
2. A Decision Dashboard that allows collaboration for decision making for different planning and operation.

As explained, FIGS. 15 and 20 show example architectures 1500 and 2000 of an example of a LAM system that include various front-end components and various back-end components. As an example, an architecture can include the following layers:

A Data Access Layer (DAL) that connects to a historian and receives current operating conditions and thresholds along with measured data.

A Business Flow Layer (BFL) that supplies pre-simulation constraints and execution controls. It can also include IAM front-end and back-end APIs, data model representation and simulation models. The back-end of the business flow layer (BFL) can provide for event management, simulation models, sending view data, etc. As an example, the back-end of the BFL can runs in a HPC environment (e.g., server, server farm, cloud, etc.).

A Decision Layer (DL) that includes different decision smart views depending upon various workflows. In such a layer, a user can visualize the current, conditions, and results from simulation run and also run one or more alternative scenarios, for example, by changing one or more simulation controls. As an example, a decision team can be called upon for validation of changes as may be flagged, etc., and then send a signal to control one or more field operations (e.g., via SCADA, etc.).

An Operation Layer (OL) that communicates to field via SCADA and/or another system, for example, to change field conditions such as, for example, gas lift valve (GLV) settings, choke settings, well head conditions, pump/compressor control etc.

As an example, the following components, sub-systems, etc., of an architecture can work in conjunction:

An IAM Web Server: This can be part of a scheduler sub-system, which makes sure each periodic time (for example monthly, etc.) will cause the LAM system to run (e.g., to evergreen one or more models). It can also communicate with an IAM web portal in a front-end and also a back-end server/VM via a router or routers. The IAM web server can coordinate updates of data in a database, model management and updates, validation, communication with IAM web portal app via REST API to run, visualize current data in the decision smart view component, etc. It can also raise a flag or alarm if validation is not successful. The IAM web server can be operatively coupled to one or more other back-end components, such as, for example, a framework that can manage various actions associated with an LAM.

A Front End Web Portal: This can be implemented as a framework that is a back-end sub-system that can be responsible for updating each individual model according to one or more types of information, which can include, for example, pre-simulation constraints from a database, a GUI, etc. It can then execute and validate each model via interactions with HPC resources to obtain results, model states, etc. It may also raise an alarm if a standalone model is not successful or an integrated asset model is not successful.

An IAM Web Portal App: This sub-system can be an interactive front-end sub-system that is interactive with a user via one or more graphical user interfaces (GUIs). The IAM web portal app can provide for executing an IAM model in a manner that picks up updated domain models and applies an asset management strategy (AMS), for example, after standalone run(s) has(have) been successful. The IAM web portal app can be configured to communicate with an IAM web server, for example, via a REST API. As an example, results can be stored in a database as well as displayed in the decision smart View component. The IAM web portal app can also send one or more operational settings to change field equipment settings (e.g., via SCADA, etc.). For example, a user can interact via one or more GUIs to cause one or more control instructions to be transmitted to one or more pieces of field equipment where the field equipment responds to such control instructions (e.g., to adjust a gas lift valve, to adjust a compressor, to adjust a sensor, etc.).

As an example, an architecture can include the following layers:
1. Data Access Layer for data capture and threshold/limits coming from one or more sources, including, for example, a historian resource and database.
2. Business Flow Layer for model integration and execution and to couple reservoir, wellbore, network, facility, economic models through direct integration so that a full model is solved at each overarching time interval, where such an approach can incorporate the richness of each model through a full simulation timeframe.
3. Presentation Layer for different decision smart views, for example, depending upon various workflows. For example, a user can visualize current conditions and results from a simulation run and also run alternative scenarios by changing simulation controls (see, e.g., the component 1920 of FIG. 19). As an example, a decision team can be utilized to validate changes and then send signals to control field operations (e.g., via SCADA, etc.). Such a visualization may optionally be on a well by well basis, or at an asset level or another level. As input parameters may be included, it can also be interactive for controlling one or more workflows and strategies for running one or more alternative scenarios.

As an example, by running an integrated asset model (IAM), a LAM system can provide output that includes one or more indications as to age of the IAM, the next live data update, the quality of one or more of the underlying models, etc. Such an approach can give confidence to end-users, being aware of the IAM being “live”.

As an example, a business layer of a LAM system can provide for executing workflow specifics such as well-to-well coordination, changes of set-points on gas injection, choke settings, etc. As an example, a GUI can render information that is output via modeling. For example, consider a workflow that can output an indication that gas lift rate at a location can be increased, for example, as an underlying proposition associated with production. In such an example, a control signal can be issued to effectuate the increase in gas lift rate where, for example, the control signal causes a change to one or more gas lift valves, etc.

As to a data access layer (DAL) of a LAM system, it can include instructions to handle various aspects of acquired data. As an example, a web portal may allow for access to a data access layer, for example, to select data sources, data types, data frequency, data processing, etc. As an example, a web portal may allow for visualization of various parameters of a data access layer.

As an example, a front-end of a LAM system can utilize an API that operates with an IAM framework (e.g., the IAM framework of Schlumberger Limited, Houston, Tex.). Such an API may be a REST API. Web services that conform to the REST architectural style, termed RESTful web services, can provide interoperability between various computing systems. RESTful web services can allow one or more requesting systems to access and manipulate textual representations of web resources by using a uniform and predefined set of stateless operations. Other kinds of web services may be utilized (e.g., such as SOAP web services) that may expose their own arbitrary sets of operations.

As an example, a LAM architecture can be built “on top of” an IAM framework. For example, consider features that direct data to an IAM web server, optionally under control via an API of the front-end of the architecture 2000. For example, the REST API may receive an API call that is directed to the IAM web server that causes the IAM web server to receive measured data as to one or more of oil rate, water rate, gas rate, field THPs, etc. As an example, an API call can be automated according to a schedule such that data are accessed and received according to a pre-determined schedule. As an example, a LAM architecture can be optional and implemented to transform an IAM to a live IAM. As an example, a IAM can be part of an IAM framework executing using HPC resources.

In the example architecture 2000, the front-end can include a web portal app that allows for control of one or more operations (e.g., control operations) using one or more techniques (e.g., SCADA, TCP/IP, etc.). In such an example, operational decision making may be performed using a web portal app such that various individuals can access a LAM system to monitor and/or control one or more field operations. As an example, where called for control action results in physical phenomena that may be different than expected, the architecture may reflect that result via receipt of data (e.g., field measurements), which can update one or more models of an IAM to assure that the IAM can be utilized to accurately assess the situation and, for example, determine a different course of action.

As an example, a LAM system can help to reduce time from months to weeks or less for model updates where such updates can be automatic and across multiple domains. As an example, a field can include ten or more wells and may include over one hundred wells. As an example, consider a field with 100 wells where an IAM covers the 100 wells and where wells may be with or without artificial lift. In such an example, a LAM system can be utilized to run scenarios, which may be optimization scenarios, to determine which wells can benefit from artificial lift. As an example, decisions for a field may be made by people on various bases. For example, as to day-to-day decisions, ten people may be involved whereas for a quarterly or yearly basis, more people may be involved. As an example, a field may have several reservoir engineers staffed for handling a reservoir model. As an example, a LAM system may reduce staffing demands at one or more periods of time. For example, where an IAM is updated and verified automatically, a reservoir engineer may be charged with review and where an issue arises, one or more reservoir engineers may be engaged. As to an IAM, across domains, a field may have twenty people (e.g., domain experts) available from time to time. As an example, a field can have an assigned asset team, which can be interdisciplinary and collaborative via LAM system features. As an example, an asset team can include a strategic team, a tactical team and an operational team, which are tasks with performing workflows with different time scales (e.g., years, to monthly, to daily, respectively). As an example, a field may be operational over a period of time from several years to tens of years.

As an example, a field can be optimized using a LAM system such that, for example, demand for EOR operations may be reduced. For example, optimization can increase oil recovery to either delay or reduce demand for EOR operations. As an example, a LAM system can help to delay EOR by meeting current production targets.

As an example, a LAM system can be utilized to receive data according to a time schedule and update models of an IAM whether the IAM is in a running state or not. Once the models are updated and verified, the IAM can inherently be updated and utilized for generating simulation results. Such results can be assessed to determine whether the IAM is valid. If the IAM is not valid, then one or more issues may be addressed that can be specific to execution of the IAM. As an example, an IAM can include a number of models that is greater than a number of models that can be run for the IAM. For example, a subset of IAM models can be selected for execution to generate results.

As an example, a LAM system can be structured according to an architecture such as shown in FIG. 15 and FIG. 20. As mentioned, an architecture can include various back-end components and various front-end components. As an example, a LAM system can output results that can be directed to a SCADA or other control system. In response, the LAM system can provide for visualization of changes in response to output to a control system.

As an example, an architecture can include a data access layer (e.g., DAL) that can provide for current operating conditions and thresholds. As an example, a LAM system can include various front-end components and various back-end components. As an example, a DAL can direct data to the front-end and the back-end. In such an example, the back-end can perform executions of models that make up an IAM using such data. As an example, models may be updated according to different time intervals. For example, a reservoir model can be updated on a weekly or monthly basis; whereas, a well and network model (e.g., surface network operatively coupled to wells, which can include downhole equipment and/or controls therefor such as gas lift, etc.) may be updated more frequently (e.g., a minutely, hourly, etc.) and a network and facility model may be updated on a different basis (e.g., weekly, monthly, etc.).

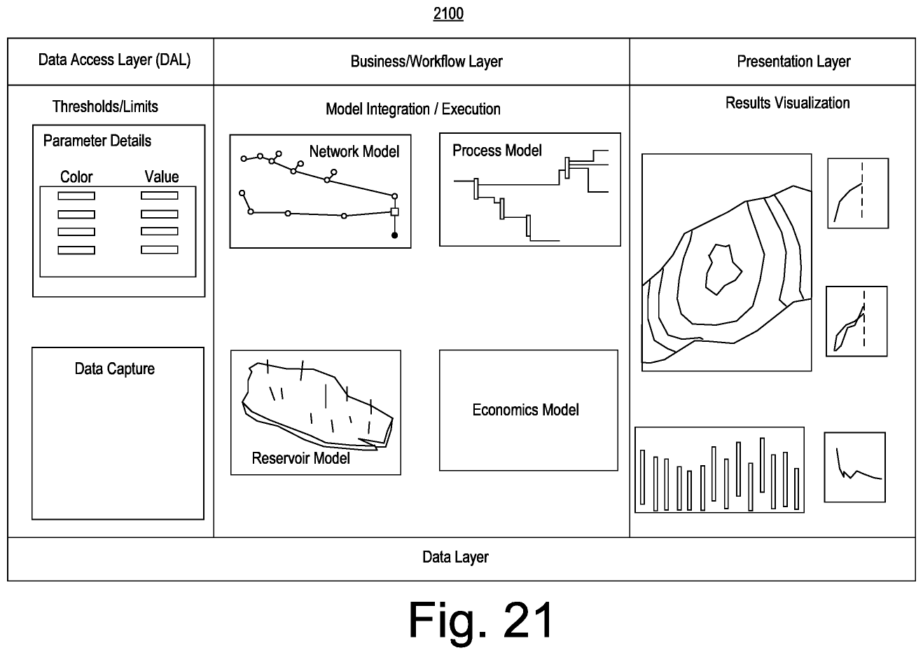

FIG. 21 shows examples of GUIs 2100 for various layers such as those of the architecture 2000 of FIG. 20. As shown, a GUI can provide for setting one or more thresholds with appropriate color indicators and can provide for views of operational data captures, for example, via a SCADA and/or other system. Views may also be provided for one or more databases, for example, consider a user accessing a network to bring a particular database online in response to a particular type of model being advanced to a particular stage of field operations or in response to call for brining another model into the fold of the LAM. In such an example, consider a treatments database that can include data as to one or more types of treatments (e.g., enhanced oil recovery, etc.). In such an approach, the LAM can properly integrate the data to assure that a model or models are properly provided with data for tasks (actual, possible alternatives, etc.) that may be performed in the field. The GUIs 2100 include various model-specific GUIs, for example, for a network model, a reservoir model, a process model and an economics model. as an example, an overall field view may be provided as a GUI where a user can select one or more portions thereof to access one or more models. As shown, the presentation layer can provide one or more GUIs for presentation of results from an LAM approach. Such results may be from one or more models where a visual comparison may be performed. As shown, a GUI can provide graphics of saturation (see also FIG. 9) such as an oil saturation distribution. A GUI can provide graphics of production data, for example, current oil production from one or more wells. As an example, a GUI can provide data for a given reservoir cross-section, which may include data from one or more wells. A GUI can render pressure trend data, which may be associated with well pressures, network pressures, etc. Pressure data may be utilized for assessing pressure-driven fluid flow and, for example, compared with one or more GUIs of production data.

One or more of the GUIs 2100 can be operatively coupled to a system such as a LAM system with an underlying architecture such as the architecture 1500 of FIG. 15 and 2000 of FIG. 20. For example, consider the front-end being configured to provide layer by layer rendering of data to generate the GUIs 2100. Such an approach may be implemented via a web portal, for example, a web portal that can be accessed via a web application (e.g., or “app”) as may be installed and executed on one or more types of networked devices (e.g., desktop, laptop, mobile, installation specific, etc.).

As an example, the GUIs 2100 may include a real-time, live camera GUI. For example, consider a site-based camera or cameras that can be activated and/or controlled. As an example, a GUI may include features for control of one or more pieces of equipment that may include imaging capabilities. For example, consider a drone or other unmanned vehicle that can be instructed to move and capture imagery pertaining to one or more field conditions. In such an example, the architecture 2000 can optionally include a real-time channel such that streaming video and/or instructions (e.g., flight control, ground control, etc.) can be implemented. Such imagery or investigation may reveal conditions that can be relevant to a LAM system where, via one or more GUIs, an operator may adjust data, workflow, etc., in response to revealed conditions (e.g., to improve an LAM).

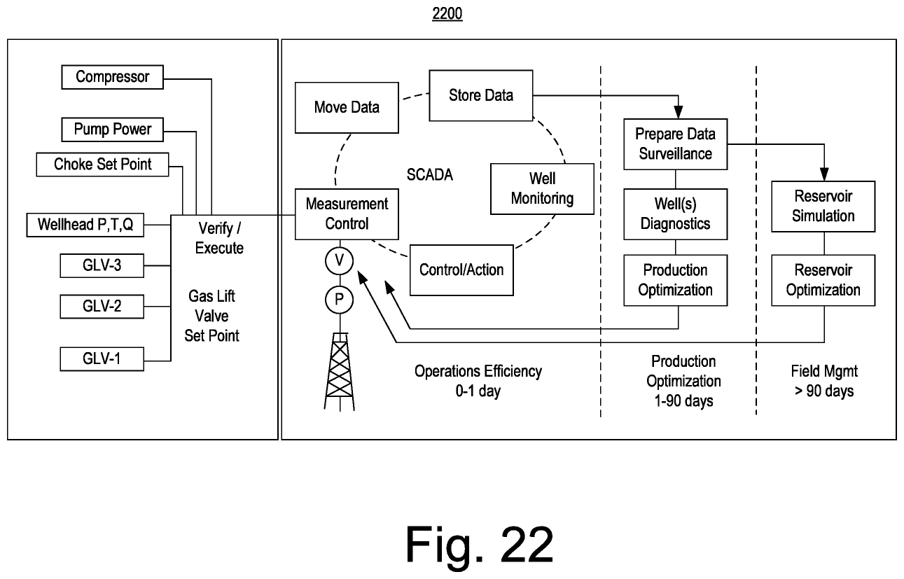

FIG. 22 shows an example of systems, rendered as one or more GUIs 2200, where the systems are operatively coupled, for example, to provide for automated operational controls using a LAM system. The one or more GUIs 2200 can include field renderings with spatial information, equipment information, parameter information, physical phenomena information, etc. FIG. 22 shows a particular well with depth metrics and equipment information as to tubing, casing, packers, liners, perforations, gas lift valves (GLVs), etc. The well includes surface equipment that has assigned channels as to pressure, temperature and flow rate. The well can be shown in a network diagram that includes various types of equipment including pumps and chokes, manifolds, separators, etc. For example, the well can be associated with a choke that is controllable where the choke controls flow of fluid to a manifold and where the manifold gathers fluid from conduits to direct the fluid to a separator. As shown, a separator may separate gas and liquid components in a fluid such that gas can be directed to a gas line with a controllable compressor and liquid directed to a liquid line with a controllable pump. As an example, liquid can be processed to be of a commodity grade and gas may be processed for one or more operations such as, for example, gas lift. As mentioned, the well includes gas lift valves labeled GLV-1, GLV-2 and GLV-3. In such a system, gas from a separator may be directed in a controllable manner for artificial lift that promotes production of fluid from the well (see, e.g., the system 600 of FIG. 6). As may be appreciated, a LAM system can account for reservoir modeling, surface network modeling, and one or more other types of modeling where an integrated approach, which can be a live approach, can assure that gas is available from a reservoir that can benefit artificial lift in a well via appropriate management/control of surface network equipment.

FIG. 22 shows a verify and execute process that can instruct one or more pieces of equipment associated with measurement and/or control. As shown, operations can be defined with respect to periods such as a zero to one day period, a one day to 90 day period, which may be understood to be one quarter of a year (e.g., four 90 day periods per year), and a longer period, for example, greater than 90 days. The various temporal frames can include a more frequent frame with measurement/control, move data, store data, individual well monitoring, and control/action, which may form a loop with feedback or other information from one or more frames that can be less frequent frames. As shown, an intermediate frame may include features for preparation of data as to surveillance, well diagnostics, production optimization, etc. Such a frame may provide output for a frame of a frequency that has greater periods, which may include features for reservoir simulation and reservoir optimization. For example, such a frame can be operatively coupled to one or more simulators such as one or more reservoir simulators. In such an example, where the frame calls for a reservoir simulator to execute, the underlying reservoir model can be managed using a LAM system to assure that it can provide results that are sound with respect to data pertaining to the field operations. As an example, one or more of the frames can call for field acquisition and/or field control.

As an example, a LAM system can be used for base model generation, revisions and execution of one or more of multiple reservoir, planning and operational workflows to improve CAPEX/OPEX costs. As an example, depending upon desired frequency(ies), different workflows related to operations efficiency, production optimization, and field management can be executed. These workflows can get measurements to validate a LAM model and, for example, send out via SCADA operational controls (or other types of control) such as:
1. Well level controls—ESP power, ICD valve opening, choke opening, gas lift valve opening, Well Head controls, etc.
2. Network level controls—Choke Set-point, Pump/Compressor power
3. Facility level controls—Compressor, Valve set points, Separator controls, etc.

Such types of controls may be for workflows related to different frequency of execution. For example, consider one or more of the following:

1. Short term operations (0-1 day)

Surveillance

Equipment Health Monitoring

Allocation

2. Medium term (1-90 days)

Production optimization workflows can be performed rapidly by connecting network or/and facility model regularly or on demand. As an example, consider validation of optimized choke openings or gas lift valve openings, which can be sent to SCADA for controlling the valves.

Debottleneck pipeline network field processing facilities.

Understand effects of transient well and reservoir behavior on production efficiency via use of “What If” Scenarios.

Understand transient behavior of complex networks by combining a Steady state to a Transient flow simulator.

3. Long term (>90 days)

Achieve more accurate forecasts by accounting for the interactions of subsurface deliverability with surface backpressure constraints

Model compositional blending, mixing, injection of multiple producing zones and reservoirs to meet product specifications

Automatically optimize artificial lift, EOR and IOR injection utilization with live asset model updated on real-time or on-demand

A LAM system can be implemented to enable collaboration that can increase efficiency of decision making. Such a system can provide for live management of various models, which can be associated with operations in a field where conditions change with respect to time. As an example, a LAM system can provide access to individuals in multiple disciplines, which may act to address one or more types of inaccuracies that may arise, for example, between boundary conditions of a reservoir, a network, and facilities such that there can be a focus on planning or operational challenges to unlock oil and maximize production NPV. As explained, interdependency between workflows and a foundation framework can be managed via a LAM that keeps the models evergreen with current changes. Such an approach can provide for an efficient system for decision making to optimize one or more assets.

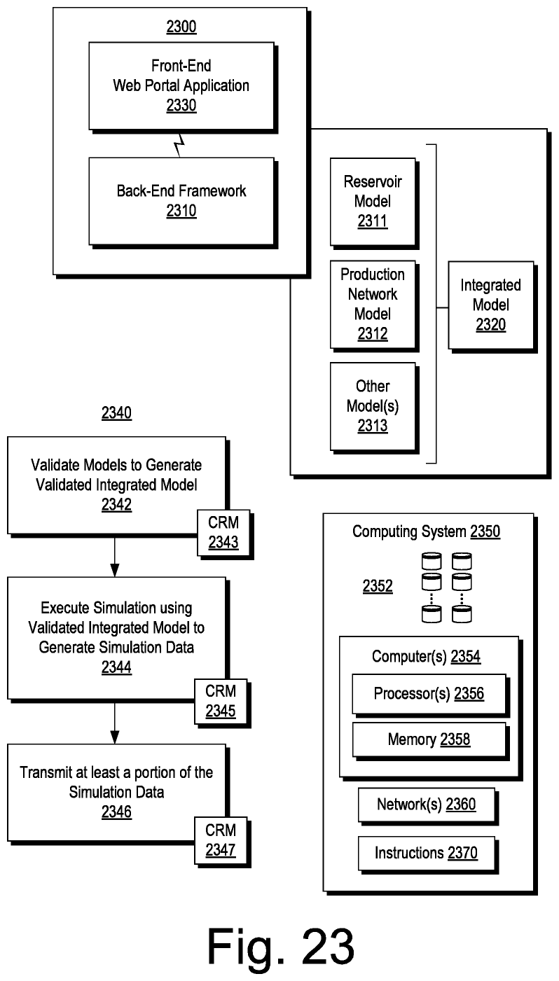

FIG. 23 shows an example of a system 2300, an example of a method 2340 and an example of a computing system 2350.

As shown, the example system 2300 can include a back-end framework 2310 that validates a reservoir model 2311 and a production network model 2312 using field data to generate a validated integrated model 2320 based at least in part on the validated reservoir model and the validated production network model; and a front-end web portal application 2330 that receives integrated model simulation data from execution of a simulation using the validated integrated model 2320.

In such an example, the system may further include a web server operatively coupled to a database that includes the field data. In such an example, the system can include an application programming interface that operatively couples the front-end web portal application 2330 and the web server.

As an example, the front-end web portal application 2330 can be operatively coupled to a URL-based router that is operatively coupled to a router of the back-end framework 2310. In such an example, the URL-based router can be operatively coupled to an application programming interface that is accessible to the front-end web portal application 2330.

As an example, in the system 2300, the back-end framework 2310 can act to generate the validated integrated model 2320 according to a set interval. In such an example, the back-end framework 2310 can act to validate the reservoir model 2311 according to a first interval and can act to validate the surface network model 2312 according to a second interval, where the first interval and the second interval differ and are less than the set interval for generation of the validated integrated model 2320.

As an example, the front-end web portal application 2330 can include a graphical user interface that includes at least one control graphic actuatable to transmit a control instruction to field equipment. In such an example, the front-end web portal application 2330 can include a graphical user interface that includes at least one graphic that renders sensor data that are responsive to actuation of the field equipment according to the control instruction.

As an example, the front-end web portal application 2330 can include a graphical user interface that includes a scenario graphic control that can generate a custom scenario, where the back-end framework 2310, responsive to receipt of the custom scenario, calls for execution of a simulation using at least one of the validated reservoir model 2311, the validated surface network model 2312 and the validated integrated model 2320.

As an example, the back-end framework 2310 can validate a processing model (see, e.g., the one or more other models 2313) using field data and generate the validated integrated model 2320 using the validated processing model.

As an example, the back-end framework can validate an economics model (see, e.g., the one or more other models 2313) using economic data and generate the validated integrated model 2320 using the validated economic model.

As an example, the system 2300 can include a control signal interface that transmits control signals to field equipment based at least in part on simulation results from execution of a simulation using the validated integrated model 2320. In such an example, the control signals can include signals for one or more of a gas lift valve setting, a choke setting, a well head condition, a pump control, a compressor control and other types of field equipment control signals.

As an example, the reservoir model 2311 can model wells in fluid communication with a reservoir and the production network model 2312 models surface conduits in fluid communication with the wells.

As an example, the back-end framework 2310 can validate a processing model (see, e.g., the one or more other models 2313) using field data and generate the validated integrated model 2320 using the validated processing model, where the processing model models processing equipment in fluid communication with at least a portion of the surface conduits (e.g., as modeled by the production network model).

As shown in the example of FIG. 23, the method 2340 can include a validation block 2342 for, via a back-end framework, validating a reservoir model and a production network model using field data to generate a validated integrated model based at least in part on the validated reservoir model and the validated production network model; executing a simulation using the validated integrated model to generate integrated model simulation data; and transmitting at least a portion of the integrated model simulation data to a front-end web portal application. In such an example, the back-end framework can be the back-end framework 2310, the front-end web portal application can be the front-end web portal application 2330, the reservoir model can be the reservoir model 2311, the production network model can be the production network model 2312, and/or the integrated model can be the integrated model 2320. As an example, in the method 2340, the executing can occur according to a set interval. In such an example, the validating the reservoir model can occur according to a first interval, where the validating the production network model can occur according to a second interval, and where the first interval and the second interval are shorter than the set interval.

As an example, one or more computer-readable storage media can include processor-executable instructions to instruct a computing system. Such computer-readable storage media can be abbreviated “CRM” (e.g., computer-readable medium or media). In the example of FIG. 23, the method 2340 is shown with various CRM blocks 2343, 2345, and 2347, which can be for various corresponding actions of the blocks 2342, 2344 and 2346, respectively.

As shown in FIG. 23, the computing system 2350 includes one or more information storage devices 2352, one or more computers 2354, one or more networks 2360 and instructions 2370. As to the one or more computers 2354, each computer may include one or more processors (e.g., or processing cores) 2356 and memory 2358 for storing instructions, for example, consider the instructions 2370 as including instructions executable by at least one of the one or more processors. As an example, one or more of the CRM blocks 2343, 2345 and 2347 may be included as sets of instructions, for example, such as the instructions 2370 of the computing system 2350. As an example, one or more of the CRM blocks 2343, 2345 and 2347 can be a computer program product. Such a product may be executable to perform one or more methods. As an example, such a product may be executable using one or more features of the system 2300, which can include one or more features of the computing system 2350.

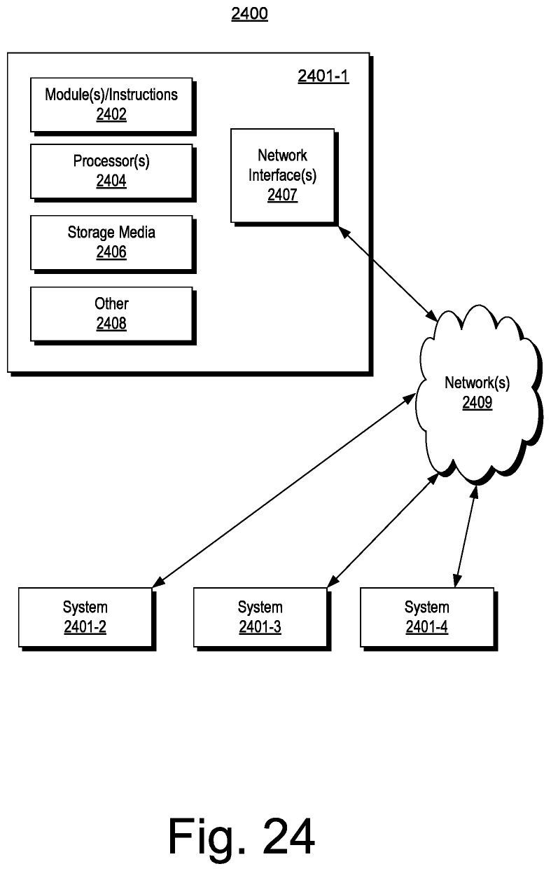

In some embodiments, a method or methods may be executed by a computing system. FIG. 24 shows an example of a system 2400 that can include one or more computing systems 2401-1, 2401-2, 2401-3 and 2401-4, which may be operatively coupled via one or more networks 2409, which may include wired and/or wireless networks.

As an example, a system can include an individual computer system or an arrangement of distributed computer systems. In the example of FIG. 24, the computer system 2401-1 can include one or more modules 2402, which may be or include processor-executable instructions, for example, executable to perform various tasks (e.g., receiving information, requesting information, processing information, simulation, outputting information, etc.).

As an example, a module may be executed independently, or in coordination with, one or more processors 2404, which is (or are) operatively coupled to one or more storage media 2406 (e.g., via wire, wirelessly, etc.). As an example, one or more of the one or more processors 2404 can be operatively coupled to at least one of one or more network interface 2407. In such an example, the computer system 2401-1 can transmit and/or receive information, for example, via the one or more networks 2409 (e.g., consider one or more of the Internet, a private network, a cellular network, a satellite network, etc.).

As an example, the computer system 2401-1 may receive from and/or transmit information to one or more other devices, which may be or include, for example, one or more of the computer systems 2401-2, etc. A device may be located in a physical location that differs from that of the computer system 2401-1. As an example, a location may be, for example, a processing facility location, a data center location (e.g., server farm, etc.), a rig location, a wellsite location, a downhole location, etc.

As an example, a processor may be or include a microprocessor, microcontroller, processor module or subsystem, programmable integrated circuit, programmable gate array, or another control or computing device.

As an example, the storage media 2406 may be implemented as one or more computer-readable or machine-readable storage media. As an example, storage may be distributed within and/or across multiple internal and/or external enclosures of a computing system and/or additional computing systems.

As an example, a storage medium or storage media may include one or more different forms of memory including semiconductor memory devices such as dynamic or static random access memories (DRAMs or SRAMs), erasable and programmable read-only memories (EPROMs), electrically erasable and programmable read-only memories (EEPROMs) and flash memories, magnetic disks such as fixed, floppy and removable disks, other magnetic media including tape, optical media such as compact disks (CDs) or digital video disks (DVDs), BLUERAY disks, or other types of optical storage, or other types of storage devices.

As an example, a storage medium or media may be located in a machine running machine-readable instructions, or located at a remote site from which machine-readable instructions may be downloaded over a network for execution.

As an example, various components of a system such as, for example, a computer system, may be implemented in hardware, software, or a combination of both hardware and software (e.g., including firmware), including one or more signal processing and/or application specific integrated circuits.

As an example, a system may include a processing apparatus that may be or include a general purpose processors or application specific chips (e.g., or chipsets), such as ASICs, FPGAs, PLDs, or other appropriate devices.

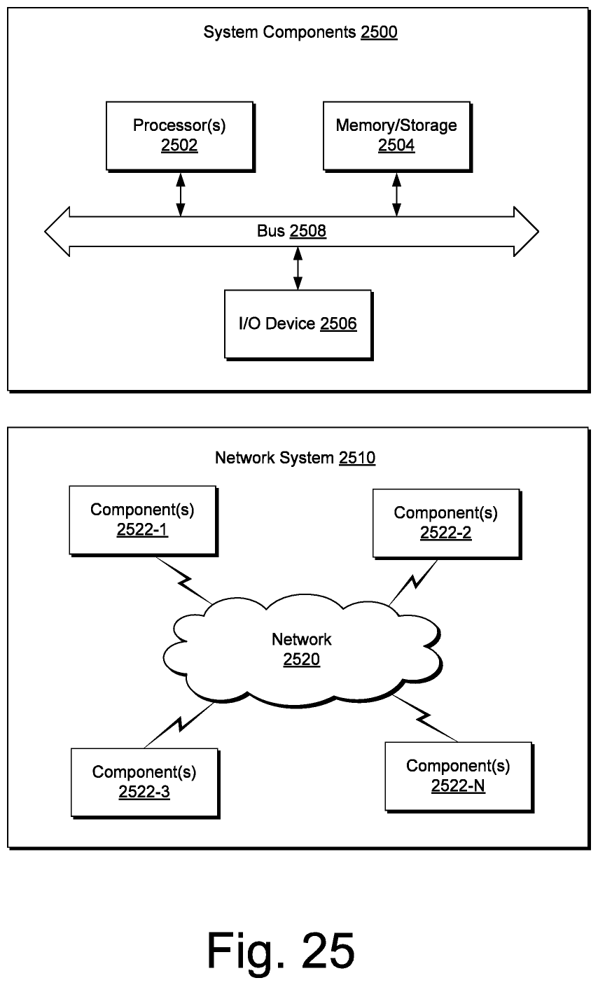

FIG. 25 shows components of an example of a computing system 2500 and an example of a networked system 2510. The system 2500 includes one or more processors 2502, memory and/or storage components 2404, one or more input and/or output devices 2506 and a bus 2508. In an example embodiment, instructions may be stored in one or more computer-readable media (e.g., memory/storage components 2504). Such instructions may be read by one or more processors (e.g., the processor(s) 2502) via a communication bus (e.g., the bus 2508), which may be wired or wireless. The one or more processors may execute such instructions to implement (wholly or in part) one or more attributes (e.g., as part of a method). A user may view output from and interact with a process via an I/O device (e.g., the device 2506). In an example embodiment, a computer-readable medium may be a storage component such as a physical memory storage device, for example, a chip, a chip on a package, a memory card, etc. (e.g., a computer-readable storage medium).

In an example embodiment, components may be distributed, such as in the network system 2510. The network system 2510 includes components 2522-1, 2522-2, 2522-3, . . . 2522-N. For example, the components 2522-1 may include the processor(s) 2502 while the component(s) 2522-3 may include memory accessible by the processor(s) 2502. Further, the component(s) 2522-2 may include an I/O device for display and optionally interaction with a method. The network may be or include the Internet, an intranet, a cellular network, a satellite network, etc.

As an example, a device may be a mobile device that includes one or more network interfaces for communication of information. For example, a mobile device may include a wireless network interface (e.g., operable via IEEE 802.11, ETSI GSM, BLUETOOTH, satellite, etc.). As an example, a mobile device may include components such as a main processor, memory, a display, display graphics circuitry (e.g., optionally including touch and gesture circuitry), a SIM slot, audio/video circuitry, motion processing circuitry (e.g., accelerometer, gyroscope), wireless LAN circuitry, smart card circuitry, transmitter circuitry, GPS circuitry, and a battery. As an example, a mobile device may be configured as a cell phone, a tablet, etc. As an example, a method may be implemented (e.g., wholly or in part) using a mobile device. As an example, a system may include one or more mobile devices.

As an example, a system may be a distributed environment, for example, a so-called “cloud” environment where various devices, components, etc. interact for purposes of data storage, communications, computing, etc. As an example, a device or a system may include one or more components for communication of information via one or more of the Internet (e.g., where communication occurs via one or more Internet protocols), a cellular network, a satellite network, etc. As an example, a method may be implemented in a distributed environment (e.g., wholly or in part as a cloud-based service).

As an example, information may be input from a display (e.g., consider a touchscreen), output to a display or both. As an example, information may be output to a projector, a laser device, a printer, etc. such that the information may be viewed. As an example, information may be output stereographically or holographically. As to a printer, consider a 2D or a 3D printer. As an example, a 3D printer may include one or more substances that can be output to construct a 3D object. For example, data may be provided to a 3D printer to construct a 3D representation of a subterranean formation. As an example, layers may be constructed in 3D (e.g., horizons, etc.), geobodies constructed in 3D, etc. As an example, holes, fractures, etc., may be constructed in 3D (e.g., as positive structures, as negative structures, etc.).

Although only a few example embodiments have been described in detail above, those skilled in the art will readily appreciate that many modifications are possible in the example embodiments. Accordingly, all such modifications are intended to be included within the scope of this disclosure as defined in the following claims. In the claims, means-plus-function clauses are intended to cover the structures described herein as performing the recited function and not only structural equivalents, but also equivalent structures. Thus, although a nail and a screw may not be structural equivalents in that a nail employs a cylindrical surface to secure wooden parts together, whereas a screw employs a helical surface, in the environment of fastening wooden parts, a nail and a screw may be equivalent structures. It is the express intention of the applicant not to invoke 35 U.S.C. § 112, paragraph 6 for any limitations of any of the claims herein, except for those in which the claim expressly uses the words “means for” together with an associated function.

What is claimed is:

1. A system comprising:
a back-end framework that validates a reservoir model and a production network model using field data to generate a validated integrated model based at least in part on the validated reservoir model and the validated production network model; and
a front-end web portal application that receives integrated model simulation data from execution of a simulation using the validated integrated model.

2. The system of claim 1, comprising a web server operatively coupled to a database that comprises the field data.

3. The system of claim 2, comprising an application programming interface that operatively couples the front-end web portal application and the web server.

4. The system of claim 1, wherein the front-end web portal application is operatively coupled to a URL-based router that is operatively coupled to a router of the back-end framework.

5. The system of claim 4, wherein the URL-based router is operatively coupled to an application programming interface that is accessible to the front-end web portal application.

6. The system of claim 1, wherein the back-end framework acts to generate the validated integrated model according to a set interval.

7. The system of claim 6, wherein the back-end framework acts to validate the reservoir model according to a first interval and acts to validate the surface network model according to a second interval, wherein the first interval and the second interval differ and are less than the set interval for generation of the validated integrated model.

8. The system of claim 1, wherein the front-end web portal application comprises a graphical user interface that comprises at least one control graphic actuatable to transmit a control instruction to field equipment.

9. The system of claim 8, wherein the front-end web portal application comprises a graphical user interface that comprises at least one graphic that renders sensor data that are responsive to actuation of the field equipment according to the control instruction.

10. The system of claim 1, wherein the front-end web portal application comprises a graphical user interface that comprises a scenario graphic control that generates a custom scenario, wherein the back-end framework, responsive to receipt of the custom scenario, calls for execution of a simulation using at least one of the validated reservoir model, the validated surface network model and the validated integrated model.

11. The system of claim 1, wherein the back-end framework validates a processing model using field data and generates the validated integrated model using the validated processing model.

12. The system of claim 1, wherein the back-end framework validates an economics model using economic data and generates the validated integrated model using the validated economic model.

13. The system of claim 1, comprising a control signal interface that transmits control signals to field equipment based at least in part on simulation results from execution of a simulation using the validated integrated model.

14. The system of claim 13, wherein the control signals comprise signals for one or more of a gas lift valve setting, a choke setting, a well head condition, a pump control, and a compressor control.

15. The system of claim 1, wherein the reservoir model models wells in fluid communication with a reservoir and wherein the production network model models surface conduits in fluid communication with the wells.

16. The system of claim 15, wherein the back-end framework validates a processing model using field data and generates the validated integrated model using the validated processing model, wherein the processing model models processing equipment in fluid communication with at least a portion of the surface conduits.

17. A method comprising:
via a back-end framework, validating a reservoir model and a production network model using field data to generate a validated integrated model based at least in part on the validated reservoir model and the validated production network model;
executing a simulation using the validated integrated model to generate integrated model simulation data; and
transmitting at least a portion of the integrated model simulation data to a front-end web portal application.

18. The method of claim 17, wherein the executing occurs according to a set interval.

19. The method of claim 18, wherein the validating the reservoir model occurs according to a first interval, wherein the validating the production network model occurs according to a second interval, and wherein the first interval and the second interval are shorter than the set interval.

20. One or more computer-readable storage media comprising processor-executable instructions to instruct a computing system to:
via a back-end framework, validate a reservoir model and a production network model using field data to generate a validated integrated model based at least in part on the validated reservoir model and the validated production network model;
execute a simulation using the validated integrated model to generate integrated model simulation data; and
transmit at least a portion of the integrated model simulation data to a front-end web portal application.
